(19) United States
(12) Patent Application Publication
(10) Pub. No.: US 2025/0185361 A1
(43) Pub. Date: Jun. 5, 2025

(54) STACKED TRANSISTORS HAVING DUAL WORK FUNCTION GATES

(71) Applicant: International Business Machines Corporation, Armonk, NY (US)

(72) Inventors: Chen Zhang, Santa Clara, CA (US); Ruilong Xie, Niskayuna, NY (US); Shay Reboh, Guilderland, NY (US); Junli Wang, Slingerlands, NY (US)

(21) Appl. No.: 18/529,029

(22) Filed: Dec. 5, 2023

(51) Int. Cl. H01L 27/092; H01L 21/822; H01L 21/8238; H01L 29/06; H01L 29/423; H01L 29/66; H01L 29/775

(52) U.S. Cl. CPC H10D 84/856; H10D 30/014; H10D 30/43; H10D 30/6735; H10D 62/121; H10D 84/0179; H10D 84/038; H10D 88/01

(57) ABSTRACT

Embodiments of the disclosure are directed to an integrated circuit (IC) that includes a bottom device and a top device positioned over the bottom device. The top device includes a first nanosheet and a second nanosheet. The bottom device includes a third nanosheet and a fourth nanosheet. A space between the first nanosheet and the second nanosheet is greater than a space between the third nanosheet and the fourth nanosheet.

### BACKGROUND

The present disclosure relates in general to fabrication methods and resulting structures for semiconductor devices. More specifically, the present disclosure relates to fabrication methods and resulting structures for stacked transistors having dual work function gates.

In contemporary semiconductor device fabrication processes, a large number of metal oxide semiconductor field effect transistors (MOSFETs), such as n-type field effect transistors (nFETs) and p-type field effect transistors (pFETs), are fabricated on a single wafer. Non-planar MOSFET architectures (e.g., fin-type FETs (FinFETs) and nanosheet FETs) can provide increased device density and increased performance over planar MOSFETs. For example, nanosheet FETs, in contrast to conventional planar MOSFETs, include a gate stack that wraps around the full perimeter of multiple stacked and spaced-apart nanosheet channel regions for a reduced device footprint and improved control of channel current flow.

To further improve wafer density, complementary FET (CFET) architectures have been developed. In CFET architectures, transistor devices are stacked on top of each other in a vertical direction, thereby forming a stacked device configuration that further reduces device footprint and further maximizes the effective channel width.

### SUMMARY

Embodiments of the disclosure are directed to an integrated circuit (IC) that includes a top device and a bottom device positioned under the top device. The top device includes a first nanosheet and a second nanosheet. The bottom device includes a third nanosheet and a fourth nanosheet. A space between the first nanosheet and the second nanosheet is greater than a space between the third nanosheet and the fourth nanosheet.

Embodiments of the disclosure are further directed to an IC having a top channel associated with a first device and a bottom channel associated with a second device. The top channel includes a first nanosheet stack that includes a first nanosheet and a second nanosheet. The bottom channel is positioned under the top channel and includes a second nanosheet stack. The second nanosheet stack includes a third nanosheet and a fourth nanosheet. A space between the first nanosheet and the second nanosheet is greater than a space between the third nanosheet and the fourth nanosheet

Embodiments of the disclosure also include fabrication methods for forming the above-described IC structures and embodying aspects of the disclosure.

Embodiments of the disclosure are further directed to a method of performing IC fabrication operations. The method includes performing a selective pinch-off operation that includes forming a top gate cavity having a first nanosheet and a second nanosheet within the top gate cavity. The method further includes forming a bottom gate cavity having a third nanosheet and a fourth nanosheet within the bottom gate cavity. A bottom gate material is deposited within the top gate cavity and the bottom gate cavity. A space between the first nanosheet and the second nanosheet is insufficient to result in the bottom gate material, when deposited, pinching off in the space between the first nanosheet and the second nanosheet. A space between the third nanosheet and the fourth nanosheet is sufficient to result in the bottom gate material, when deposited, pinching off in the space between the third nanosheet and the fourth nanosheet.

Additional features and advantages are realized through techniques described herein. Other embodiments and aspects are described in detail herein. For a better understanding, refer to the description and to the drawings.

### BRIEF DESCRIPTION OF THE DRAWINGS

The subject matter which is regarded as embodiments is particularly pointed out and distinctly claimed in the claims at the conclusion of the specification. The foregoing and other features and advantages of the embodiments are apparent from the following detailed description taken in conjunction with the accompanying drawings in which:

FIG. 1 depicts a top-down view of a simplified nanosheet-based reference structure that provides a reference point for the three-dimensional and cross-sectional views (X-view and Y-view) shown in FIGS. 2, 3, and 4B-21;

FIG. 2 depicts a three-dimensional view of a nanosheet FET capable of incorporating aspects of the disclosure;

FIG. 3 depicts a sequence of simplified diagrams illustrating a novel selective pinch-off operation in accordance with aspects of the disclosure;

FIG. 4A depicts a flow diagram illustrating a methodology in accordance with aspects of the disclosure;

FIGS. 4B-4G depict multiple cross-sectional views of a portion of an IC after application IC fabrication operations that incorporate a novel selective pinch-off operation in accordance with aspects of the disclosure, in which:

FIG. 4B depicts cross-sectional views of the portion of the IC after initial IC fabrication operations in accordance with aspects of the present disclosure;

FIG. 4C depicts cross-sectional views of the portion of the IC after subsequent IC fabrication operations in accordance with aspects of the present disclosure;

FIG. 4D depicts cross-sectional views of the portion of the IC after subsequent IC fabrication operations in accordance with aspects of the present disclosure;

FIG. 4E depicts cross-sectional views of the portion of the IC after subsequent IC fabrication operations in accordance with aspects of the present disclosure;

FIG. 4F depicts cross-sectional views of the portion of the IC after subsequent IC fabrication operations in accordance with aspects of the present disclosure; and

FIG. 4G depicts cross-sectional views of the portion of the IC after subsequent IC fabrication operations in accordance with aspects of the present disclosure;

FIGS. 5-21 depict multiple cross-sectional views of a portion of an IC after IC fabrication operations that include a novel selective pinch-off operation in accordance with aspects of the disclosure, in which:

FIG. 5 depicts cross-sectional views of the portion of the IC after initial IC fabrication operations in accordance with aspects of the present disclosure;

FIG. 6 depicts cross-sectional views of the portion of the IC after subsequent IC fabrication operations in accordance with aspects of the present disclosure;

FIG. 7 depicts cross-sectional views of the portion of the IC after subsequent IC fabrication operations in accordance with aspects of the present disclosure;

FIG. 8 depicts cross-sectional views of the portion of the IC after subsequent IC fabrication operations in accordance with aspects of the present disclosure;

FIG. 9 depicts cross-sectional views of the portion of the IC after subsequent IC fabrication operations in accordance with aspects of the present disclosure;

FIG. 10 depicts cross-sectional views of the portion of the IC after subsequent IC fabrication operations in accordance with aspects of the present disclosure;

FIG. 11 depicts cross-sectional views of the portion of the IC after subsequent IC fabrication operations in accordance with aspects of the present disclosure;

FIG. 12 depicts cross-sectional views of the portion of the IC after subsequent IC fabrication operations in accordance with aspects of the present disclosure;

FIG. 13 depicts cross-sectional views of the portion of the IC after subsequent IC fabrication operations in accordance with aspects of the present disclosure;

FIG. 14 depicts cross-sectional views of the portion of the IC after subsequent IC fabrication operations in accordance with aspects of the present disclosure;

FIG. 15 depicts cross-sectional views of the portion of the IC after subsequent IC fabrication operations in accordance with aspects of the present disclosure;

FIG. 16 depicts cross-sectional views of the portion of the IC after subsequent IC fabrication operations in accordance with aspects of the present disclosure;

FIG. 17 depicts cross-sectional views of the portion of the IC after subsequent IC fabrication operations in accordance with aspects of the present disclosure;

FIG. 18 depicts cross-sectional views of the portion of the IC after subsequent IC fabrication operations in accordance with aspects of the present disclosure;

FIG. 19 depicts cross-sectional views of the portion of the IC after subsequent IC fabrication operations in accordance with aspects of the present disclosure;

FIG. 20 depicts cross-sectional views of the portion of the IC after subsequent IC fabrication operations in accordance with aspects of the present disclosure; and

FIG. 21 depicts cross-sectional views of the portion of the IC after subsequent IC fabrication operations in accordance with aspects of the present disclosure.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two- or three-digit reference numbers. With minor exceptions, the leftmost digit(s) of each reference number correspond to the figure in which its element is first illustrated.

### DETAILED DESCRIPTION

Embodiments of the disclosure are directed to an integrated circuit (IC) that includes a top device and a bottom device positioned under the top device. The top device includes a first nanosheet and a second nanosheet. The bottom device includes a third nanosheet and a fourth nanosheet. A space between the first nanosheet and the second nanosheet is greater than a space between the third nanosheet and the fourth nanosheet.

The above-described embodiments of the disclosure provide technical benefits and technical effects. For example, because the space between the first nanosheet and the second nanosheet is greater than a space between the third nanosheet and the fourth nanosheet, a novel selective pinch-off operation can be used to deposit a bottom gate around the third nanosheet and the fourth nanosheet, and to further deposit a top gate, different from the bottom gate, around the first nanosheet and the second nanosheet. In some embodiments of the disclosure, the selective pinch-off operation includes conformally depositing a bottom gate material on exposed surfaces within a top gate cavity and a bottom gate cavity. The first nanosheet and the second nanosheet are within the top gate cavity, and the third nanosheet and the fourth nanosheet are within the bottom gate cavity. The space between the first nanosheet and the second nanosheet is insufficient to result in the conformally deposited bottom gate material pinching off in the space between the first nanosheet and the second nanosheet, and the space between the third nanosheet and the fourth nanosheet is sufficient to result in the conformally deposited bottom gate material pinching off in the space between the third nanosheet and the fourth nanosheet. Subsequent to removing the bottom gate material from the top gate cavity, a top gate material is deposited within the top gate cavity, thereby forming the bottom gate around the third nanosheet and the fourth nanosheet, and further forming the top gate around the first nanosheet and the second nanosheet.

Without benefit of embodiments of the disclosure, the above-described process of removing the bottom gate material from the top gate cavity is challenging because the presence of the first and second nanosheets in the top gate cavity require the use of an isotropic etch that etches laterally to remove the bottom gate material from the space between the first nanosheet and the second nanosheet. However, embodiments of the disclosure recognize and leverage a heretofore unappreciated observation that, if the space between the first nanosheet and the second nanosheet in the top gate cavity is not sufficiently greater than the space between the third nanosheet and the fourth nanosheet in the bottom gate cavity, an isotropic etch that is applied long enough to remove the bottom gate material from the top gate cavity will also remove an unacceptable amount of the bottom gate material from the bottom gate cavity, thereby requiring complicated, time consuming, and unreliable operations to rebuild the removed portions of the bottom gate material before the top gate material is deposited. Because embodiments of the disclosure provide a space between the first nanosheet and the second nanosheet that is insufficient to result in the conformally deposited bottom gate material pinching off in the space between the first nanosheet and the second nanosheet, and because embodiments of the disclosure substantially concurrently provide a space between the third nanosheet and the fourth nanosheet that is sufficient to result in the conformally deposited bottom gate material pinching off in the space between the third nanosheet and the fourth nanosheet, an isotropic etch that is applied long enough to remove the bottom gate material from the top gate cavity will not also remove an unacceptable amount of the bottom gate material from the bottom gate cavity, thereby eliminating the need to apply complicated, time consuming, and unreliable operations to rebuild removed portions of the bottom gate material before the top gate material is deposited.

In addition to one or more of the features described above, or as an alternative to any of the foregoing embodiments of the disclosure, the IC can further include a stacked device configuration that includes the top device, the bottom device, and an isolation region operable to electrically isolate the bottom device from the top device. A top gate is around exposed surfaces of the first nanosheet and the second nanosheet, and a bottom gate is around exposed surface of the third nanosheet and the fourth nanosheet.

The above-described embodiments of the disclosure provide technical benefits and technical effects. For example, the stacked device configuration further improves wafer density, allows further maximization of the effective channel width, further reduces device footprint, and provides the necessary electrical isolation for the stacked devices configuration. Additionally, because the space between the first nanosheet and the second nanosheet is greater than a space between the third nanosheet and the fourth nanosheet, the previously-described novel selective pinch-off operation can be used to deposit the bottom gate around the third nanosheet and the fourth nanosheet, and to further deposit the top gate around the first nanosheet and the second nanosheet.

In addition to one or more of the features described above, or as an alternative to any of the foregoing embodiments of the disclosure, a width dimension of the top gate is different from a width dimension of the bottom gate.

The above-described embodiments of the disclosure provide technical benefits and technical effects. For example, by providing a width dimension of the top gate that is different from a width dimension of the bottom gate, the top gate can be larger than the bottom gate, thereby enabling the top gate to be fabricated such that it includes a relatively thick gate dielectric. The relatively thick gate dielectric can be implemented as a so-called extended-gate (EG) dielectric, which is configured to tolerate larger gate threshold voltages (e.g., larger than required for transistor switching operations) that are required by electronic devices such as MOSFETs that function as memory cells. In some embodiments of the disclosure, the EG dielectric thickness is selected to increase the threshold voltage V_{T} that can be tolerated by top gate. In some embodiments of the disclosure, EG dielectric can include high-k dielectric layers operable to modify a work function property of the top gate.

In addition to one or more of the features described above, or as an alternative to any of the foregoing embodiments of the disclosure, a work function of the top gate is different from a work function of the bottom gate.

The above-described embodiments of the disclosure provide technical benefits and technical effects. For example, because the space between the first nanosheet and the second nanosheet is greater than a space between the third nanosheet and the fourth nanosheet, the novel selective pinch-off operation can be used to further facilitate providing the top gate with different characteristics than the bottom gate. In some embodiments of the disclosure, the different characteristics can include different work function characteristics, which enable the top and bottom gates to tolerate different threshold voltage V_{T}. Improving the ability to mix and match electronic devices having different V_{T} in the stacked device configuration improves flexibility in generating the design and floorplan of the IC.

In addition to one or more of the features described above, or as an alternative to any of the foregoing embodiments of the disclosure, the IC can further include top S/D regions electronically coupled to the first nanosheet, along with bottom S/D regions electronically coupled to the third nanosheet. A doping type of the top S/D regions is different from a doping type of the bottom S/D regions.

The above-described embodiments of the disclosure provide technical benefits and technical effects. For example, because the space between the first nanosheet and the second nanosheet is greater than a space between the third nanosheet and the fourth nanosheet, the novel selective pinch-off operation can be used to further facilitate providing the first device with different characteristics than the second device. In some embodiments of the disclosure, the different characteristics can include providing a doping type of the top S/D regions that is different from a doping type of the bottom S/D regions. For example, the doping type of the top S/D regions can be p-type, and the doping type of the bottom S/D regions can be n-type. Alternatively, the doping type of the top S/D regions can be n-type, and the doping type of the bottom S/D regions can be p-type transistor. The ability to mix and match different S/D doping types in the stacked device configuration provides improved flexibility in generating the design and floorplan of the IC.

Embodiments of the disclosure also include fabrication methods for forming the above-described embodiments of the disclosure, where the fabrication methods provide substantially the same features, functions, technical benefits, and technical effects as the above-described IC structures embodying aspects of the disclosure.

Embodiments of the disclosure are further directed to an IC having a top channel associated with a first device and a bottom channel associated with a second device. The top channel includes a first nanosheet stack that includes a first nanosheet and a second nanosheet. The bottom channel is positioned below the top channel and includes a second nanosheet stack. The second nanosheet stack includes a third nanosheet and a fourth nanosheet. A space between the first nanosheet and the second nanosheet is greater than a space between the third nanosheet and the fourth nanosheet

The above-described embodiments of the disclosure provide technical benefits and technical effects. For example, because the space between the first nanosheet and the second nanosheet is greater than a space between the third nanosheet and the fourth nanosheet, a novel selective pinch-off operation can be used to deposit a bottom gate around the third nanosheet and the fourth nanosheet, and to further deposit a top gate, different from the bottom gate, around the first nanosheet and the second nanosheet. In some embodiments of the disclosure, the selective pinch-off operation includes conformally depositing a bottom gate material on exposed surfaces within a top gate cavity and a bottom gate cavity. The first nanosheet and the second nanosheet are within the top gate cavity, and the third nanosheet and the fourth nanosheet are within the bottom gate cavity. The space between the first nanosheet and the second nanosheet is insufficient to result in the conformally deposited bottom gate material pinching off in the space between the first nanosheet and the second nanosheet, and the space between the third nanosheet and the fourth nanosheet is sufficient to result in the conformally deposited bottom gate material pinching off in the space between the third nanosheet and the fourth nanosheet. Subsequent to removing the bottom gate material from the top gate cavity, a top gate material is deposited within the top gate cavity, thereby forming the bottom gate around the third nanosheet and the fourth nanosheet, and further forming the top gate around the first nanosheet and the second nanosheet.

Without benefit of embodiments of the disclosure, the above-described process of removing the bottom gate material from the top gate cavity is challenging because the presence of the first and second nanosheets in the top gate cavity requires the use of an isotropic etch that etches laterally to remove the bottom gate material from the space between the first nanosheet and the second nanosheet. However, embodiments of the disclosure recognize and leverage a heretofore unappreciated observation that, if the space between the first nanosheet and the second nanosheet in the top gate cavity is not sufficiently greater than the space between the third nanosheet and the fourth nanosheet in the bottom gate cavity, an isotropic etch that is applied long enough to remove the bottom gate material from the top gate cavity will also remove an unacceptable amount of the bottom gate material from the bottom gate cavity, thereby requiring complicated, time consuming, and unreliable operations to rebuild the removed portions of the bottom gate material before the top gate material is deposited. Because embodiments of the disclosure provide a space between the first nanosheet and the second nanosheet that is insufficient to result in the conformally deposited bottom gate material pinching off in the space between the first nanosheet and the second nanosheet, and because embodiments of the disclosure substantially concurrently provide a space between the third nanosheet and the fourth nanosheet that is sufficient to result in the conformally deposited bottom gate material pinching off in the space between the third nanosheet and the fourth nanosheet, an isotropic etch that is applied long enough to remove the bottom gate material from the top gate cavity will not also remove an unacceptable amount of the bottom gate material from the bottom gate cavity, thereby eliminating the need to apply complicated, time consuming, and unreliable operations to rebuild removed portions of the bottom gate material before the top gate material is deposited.

In addition to one or more of the features described above, or as an alternative to any of the foregoing embodiments of the disclosure, the IC can further include a top gate is around exposed surfaces of the first nanosheet and the second, along with a bottom gate around exposed surface of the third nanosheet and the fourth nanosheet.

The above-described embodiments of the disclosure provide technical benefits and technical effects. For example, because the space between the first nanosheet and the second nanosheet is greater than a space between the third nanosheet and the fourth nanosheet, the previously-described novel selective pinch-off operation can be used to deposit the bottom gate around the third nanosheet and the fourth nanosheet, and to further deposit the top gate around the first nanosheet and the second nanosheet.

In addition to one or more of the features described above, or as an alternative to any of the foregoing embodiments of the disclosure, a width dimension of the top gate is different from a width dimension of the bottom gate.

The above-described embodiments of the disclosure provide technical benefits and technical effects. For example, by providing a width dimension of the top gate that is different from a width dimension of the bottom gate, the top gate can be larger than the bottom gate, thereby enabling the top gate to be fabricated such that it includes a relatively thick gate dielectric. The relatively thick gate dielectric can be implemented as a so-called extended-gate (EG) dielectric, which is configured to tolerate larger gate threshold voltages (e.g., larger than required for transistor switching operations) that are required by electronic devices such as MOSFETs that function as memory cells. In some embodiments of the disclosure, the EG dielectric thickness is selected to increase the threshold voltage V_{T} that can be tolerated by top gate. In some embodiments of the disclosure, EG dielectric can include high-k dielectric layers operable to modify a work function property of the top gate.

In addition to one or more of the features described above, or as an alternative to any of the foregoing embodiments of the disclosure, a work function of the top gate is different from a work function of the bottom gate.

The above-described embodiments of the disclosure provide technical benefits and technical effects. For example, because the space between the first nanosheet and the second nanosheet is greater than a space between the third nanosheet and the fourth nanosheet, the novel selective pinch-off operation can be used to further facilitate providing the top gate with different characteristics than the bottom gate. In some embodiments of the disclosure, the different characteristics can include different work function characteristics, which enable the top and bottom gates to tolerate different threshold voltage V_{T}. Improving the ability to mix and match electronic devices having different V_{T} in the first device and the second device improves flexibility in generating the design and floorplan of the IC.

In addition to one or more of the features described above, or as an alternative to any of the foregoing embodiments of the disclosure, the IC can further include top S/D regions electronically coupled to the first nanosheet, along with bottom S/D regions electronically coupled to the third nanosheet. A doping type of the top S/D regions is different from a doping type of the bottom S/D regions. The first device can be an n-type transistor while the second device can be a p-type transistor. Alternatively, the first device can be a p-type transistor while the second device can be an n-type transistor

The above-described embodiments of the disclosure provide technical benefits and technical effects. For example, because the space between the first nanosheet and the second nanosheet is greater than a space between the third nanosheet and the fourth nanosheet, the novel selective pinch-off operation can be used to further facilitate providing the first device with different characteristics than the second device. In some embodiments of the disclosure, the different characteristics can include providing a doping type of the top S/D regions that is different from a doping type of the bottom S/D regions. For example, the doping type of the top S/D regions can be p-type, and the doping type of the bottom S/D regions can be n-type. Alternatively, the doping type of the top S/D regions can be n-type, and the doping type of the bottom S/D regions can be p-type transistor. The ability to mix and match different S/D doping types in the first device and the second device provides improved flexibility in generating the design and floorplan of the IC.

Embodiments of the disclosure also include fabrication methods for forming the above-described embodiments of the disclosure, where the fabrication methods provide substantially the same features, functions, technical benefits, and technical effects as the above-described IC structures embodying aspects of the disclosure.

Embodiments of the disclosure are further directed to a method of performing IC fabrication operations. The method includes performing a selective pinch-off operation that includes forming a top gate cavity having a first nanosheet and a second nanosheet within the top gate cavity. The method further includes forming a bottom gate cavity having a third nanosheet and a fourth nanosheet within the bottom gate cavity. A bottom gate material is deposited within the top gate cavity and the bottom gate cavity. A space between the first nanosheet and the second nanosheet is insufficient to result in the bottom gate material, when deposited, pinching off in the space between the first nanosheet and the second nanosheet. A space between the third nanosheet and the fourth nanosheet is sufficient to result in the bottom gate material, when deposited, pinching off in the space between the third nanosheet and the fourth nanosheet.

The above-described embodiments of the disclosure provide technical benefits and technical effects. For example, without benefit of the selective pinch-off operations, the process of removing the bottom gate material from the top gate cavity is challenging because the presence of the first and second nanosheets in the top gate cavity requires the use of an isotropic etch that etches laterally to remove the bottom gate material from the space between the first nanosheet and the second nanosheet. Embodiments of the disclosure recognize and leverage a heretofore unappreciated observation that, if the space between the first nanosheet and the second nanosheet in the top gate cavity is not sufficiently greater than the space between the third nanosheet and the fourth nanosheet in the bottom gate cavity, an isotropic etch that is applied long enough to remove the bottom gate material from the top gate cavity will also remove an unacceptable amount of the bottom gate material from the bottom gate cavity, thereby requiring complicated, time consuming, and unreliable operations to rebuild the removed portions of the bottom gate material before the top gate material is deposited. Because embodiments of the disclosure provide a space between the first nanosheet and the second nanosheet that is insufficient to result in the conformally deposited bottom gate material pinching off in the space between the first nanosheet and the second nanosheet, and because embodiments of the disclosure substantially concurrently provide a space between the third nanosheet and the fourth nanosheet that is sufficient to result in the conformally deposited bottom gate material pinching off in the space between the third nanosheet and the fourth nanosheet, an isotropic etch that is applied long enough to remove the bottom gate material from the top gate cavity will not also remove an unacceptable amount of the bottom gate material from the bottom gate cavity, thereby eliminating the need to apply complicated, time consuming, and unreliable operations to rebuild removed portions of the bottom gate material before the top gate material is deposited.

In addition to one or more of the features described above, or as an alternative to any of the foregoing embodiments of the disclosure, the method of performing IC fabrication operations further includes, subsequent to removing the bottom gate material from top gate cavity, depositing a top gate material within the top gate cavity. The method of performing IC fabrication operations can further include forming a first section of an isolation region operable to define a passage that connects the top gate cavity and the bottom gate cavity. The first section of the isolation region is operable to block an etchant in the top gate cavity from accessing a first portion of the bottom gate material in the bottom gate cavity. The isolation region is further operable to allow the etchant in the top gate cavity to access a second portion of the bottom gate material in the bottom gate cavity. In some embodiments of the disclosure, the first portions of the bottom gate material is larger than the second portion of the bottom gate material.

The above-described embodiments of the disclosure provide technical benefits and technical effects. For example, in embodiments of the disclosure, a removal process that removes the bottom gate material from the first nanosheet and the second nanosheet can be implemented as any suitable selective isotropic etch operation that etches in all directions. The selective isotropic etch operation used to remove the bottom gate material from the top gate cavity will eventually begin to etch portions of the bottom gate material within the passage that connects the top gate cavity to the bottom gate cavity. At this stage of the selective isotropic etch operation, the first section of the isolation region covers a first portion of the bottom gate material, and a second portion of the bottom gate material that is within the passage is exposed to the selective isotropic etchant. In accordance with aspects of the disclosure, the vertical height dimension of the first section of the isolation region, along with a width dimension of the passage, can be configured and arranged to slow and/or control the amount of the selective isotropic etchant that reaches and etches the second portion of the gate material that is within the passage. Accordingly, the selective isotropic etchant used to remove the bottom gate material from the top gate cavity also reduces a top surface of the second portion of the bottom gate material that remains in the bottom gate cavity 1710. In some embodiments of the disclosure, the vertical height dimension of the first section of the isolation region and/or the width dimension of the passage are selected such that the selective isotropic etchant completes the removal of the bottom gate material from the top gate cavity before the selective isotropic etchant removes enough of the second portion of the bottom gate material in the passage that the selective isotropic etchant reaches and begins to isotropically etch (i.e., etch in all directions) the first portion of the bottom gate material that is beneath the first section of the isolation region.

For the sake of brevity, conventional techniques related to semiconductor device and IC fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to a description of technologies that are more specifically relevant to aspects of the present disclosure, semiconductor devices (e.g., FETs) are formed using active regions of a wafer. The active regions are defined by isolation regions used to separate and electrically isolate adjacent semiconductor devices. For example, in an IC having a plurality of MOSFETs, each MOSFET has a source and a drain that are formed in an active region of a semiconductor layer by implanting n-type or p-type impurities in the layer of semiconductor material. Disposed between the source and the drain is a channel (or body) region. Disposed above the body region is a gate electrode. The gate electrode and the body are spaced apart by a gate dielectric layer.

MOSFET-based ICs are fabricated using so-called complementary metal oxide semiconductor (CMOS) fabrication technologies. In general, CMOS is a technology that uses complementary and symmetrical pairs of p-type and n-type MOSFETs to implement logic functions. The channel region connects the source and the drain, and electrical current flows through the channel region from the source to the drain. The electrical current flow is induced in the channel region by a voltage applied at the gate electrode.

The wafer footprint of an FET is related to the electrical conductivity of the channel material. If the channel material has a relatively high conductivity, the FET can be made with a correspondingly smaller wafer footprint. A known method of increasing channel conductivity and decreasing FET size is to form the channel as a nanostructure. For example, a so-called gate-all-around (GAA) nanosheet FET is a known architecture for providing a relatively small FET footprint by forming the channel region as a series of thin nanosheets (e.g., about 3 nm to about 8 nm thick). In a known GAA configuration, a nanosheet-based FET includes a source region, a drain region and stacked, spaced-apart nanosheet channels between the source and drain regions. A gate surrounds the stacked, spaced-apart nanosheet channels and regulates electron flow through the nanosheet channels between the source and drain regions.

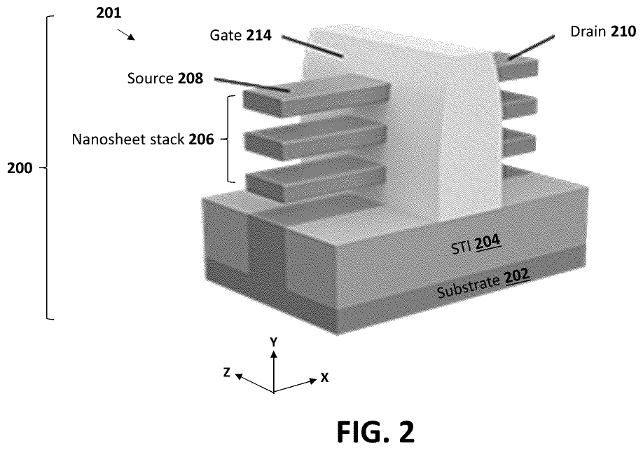

GAA nanosheet FETs (e.g., the GAA nanosheet FET 201 shown in FIG. 2) are fabricated by forming alternating layers of non-sacrificial nanosheets and sacrificial nanosheets. The sacrificial nanosheets are released from the non-sacrificial nanosheets before the FET device is finalized. For n-type FETs, the non-sacrificial nanosheets are typically silicon (Si) and the sacrificial nanosheets are typically silicon germanium (SiGe). For p-type FETs, the non-sacrificial nanosheets can be SiGe and the sacrificial nanosheets can be Si. In some implementations, the non-sacrificial nanosheet of a p-type FET can be SiGe or Si, and the sacrificial nanosheets can be Si or SiGe. Forming the GAA nanosheets from alternating layers of non-sacrificial nanosheets formed from a first type of semiconductor material (e.g., Si for n-type FETs, and SiGe for p-type FETs) and sacrificial nanosheets formed from a second type of semiconductor material (e.g., SiGe for n-type FETs, and Si for p-type FETs) provides superior non-sacrificial electrostatics control, which is necessary for continuously scaling gate lengths down to seven (7) nanometer CMOS technology and below. The use of multiple layered SiGe/Si sacrificial/non-sacrificial nanosheets (or Si/SiGe sacrificial/non-sacrificial nanosheets) to form the channel regions in GAA nanosheet FET semiconductor devices provides desirable device characteristics, including the introduction of strain at the interface between SiGe and Si.

GAA nanosheet FETs can be implemented in a so-called complementary FET (CFET) architecture. In CFET architectures, FETs are stacked on stop of one another. A CFET architecture can stack one n-type FET on top of a p-type FET wire, or two n-type FETs on top of two p-type FETs. This “folding” of the n-type FET and p-type FET eliminates the n-to-p separation bottleneck, thereby reducing the cell active area footprint. Because a CFET architecture stacks both n-type and p-type devices on each other, device footprint is reduced.

Fabricating GAA nanosheet FETs in a CFET (or stacked device configuration) architecture presents a number of challenges. For example, because n-type FETs and p-type FETs require different work function metals (WFMs) and different threshold voltages in their respective gates, when fabricating GAA nanosheet FETs in a CFET architecture, it is necessary to form an n-type-compatible WFM for one GAA nanosheet FET in the CFET architecture while also forming a p-type-compatible WFM for another GAA nanosheet FET in the CFET architecture. A known method of forming the gates in a CFET architecture is forming a gate cavity that extends from the top FET into the bottom FET, depositing the bottom gate material in the entire gate cavity, then replacing the portion of the bottom gate material in a top region of the gate cavity with a top gate material. This process. The presence of nanosheets in the top region of the gate cavity requires the use of an isotropic etch process that etches laterally to remove the bottom gate material from the space between adjacent nanosheets in the top region of the gate cavity. However, for conventional GAA nanosheet FETs arranged in a CFET architecture, an isotropic etch that is applied long enough to remove the bottom gate material from the top region of the gate cavity region will also remove an unacceptable amount of the bottom gate material from the bottom region of the gate cavity, thereby requiring the development of complicated, time consuming, and unreliable operations to rebuild the removed portions of the bottom gate material before the top gate material is deposited. The above-described problems associated with using an isotropic etch to remove the bottom gate material from the top region of the gate cavity is an impediment to leveraging the full range of benefits that can result from implementing GAA nanosheet transistors in a CFET architecture.

Turning now to an overview of aspects of the disclosure, embodiments of the disclosure address the problems associated with using an isotropic etch to remove the bottom gate material from the top region of the gate cavity by providing spacing around the nanosheets in the top region of the gate cavity that is insufficient to result in a conformally deposited bottom gate material pinching off in the top region of the gate cavity, and by further providing spacing around the nanosheets in the bottom region of the gate cavity that is sufficient to result in the conformally deposited bottom gate material pinching off in the bottom region of the gate cavity. Because embodiments of the disclosure provide spacing around the nanosheets in the top region of the gate cavity that is insufficient to result in a conformally deposited bottom gate material pinching off in the top region of the gate cavity while also providing spacing around the nanosheets in the bottom region of the gate cavity that is sufficient to result in the conformally deposited bottom gate material pinching off in the top region of the gate cavity, an isotropic etch that is applied long enough to remove the bottom gate material from the top region of the gate cavity will not also remove an unacceptable amount of the bottom gate material from the bottom region of the gate cavity, thereby eliminating the need to apply complicated, time consuming, and unreliable operations to rebuild removed portions of the bottom gate material before the top gate material is deposited.

Additionally, by providing a width dimension of the top gate that is different from a width dimension of the bottom gate, embodiments of the disclosure facilitate the efficient fabrication of a top gate having a larger width dimension than the bottom gate, thereby enabling the top gate to be fabricated such that it includes a relatively thick gate dielectric. The relatively thick gate dielectric can be implemented as a so-called extended-gate (EG) dielectric, which is configured to tolerate larger gate threshold voltages (e.g., larger than required for transistor switching operations) that are required by electronic devices such as MOSFETs that function as memory cells. In some embodiments of the disclosure, the EG dielectric thickness is selected to increase the threshold voltage V_{T} that can be tolerated by top gate. In some embodiments of the disclosure, EG dielectric can include high-k dielectric layers operable to modify a work function property of the top gate.

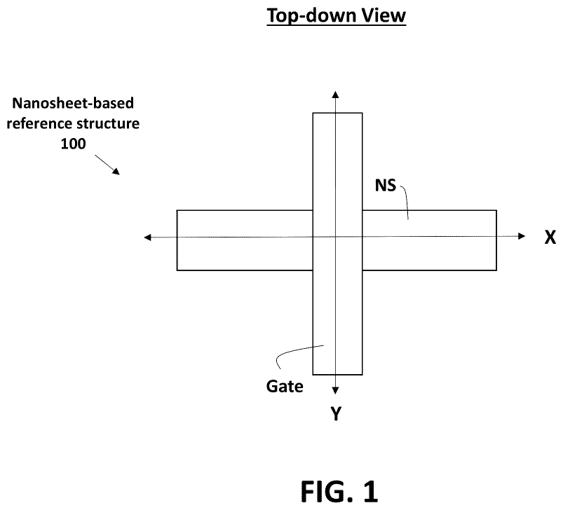

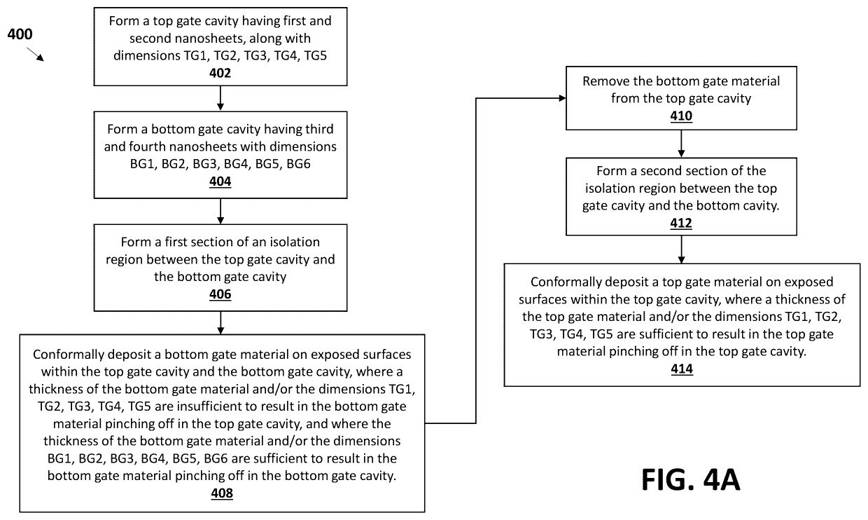

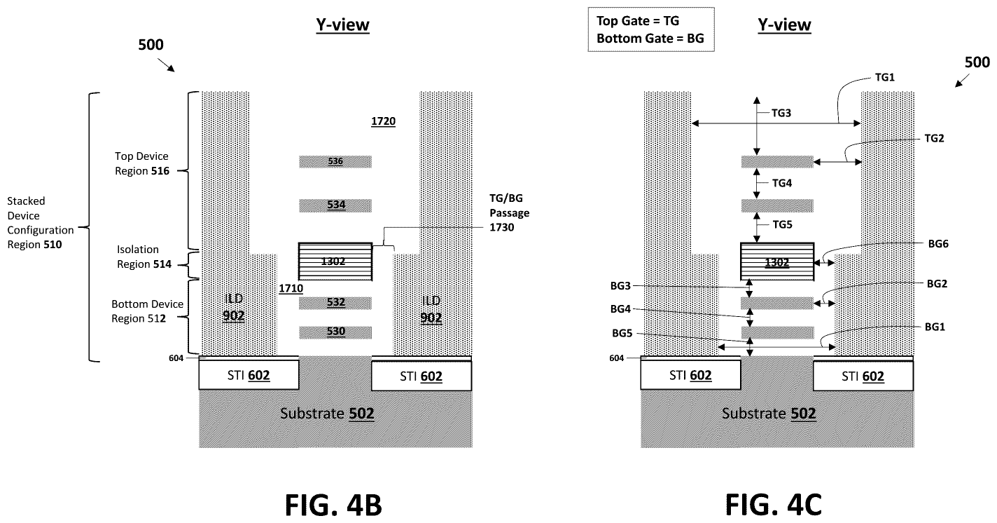

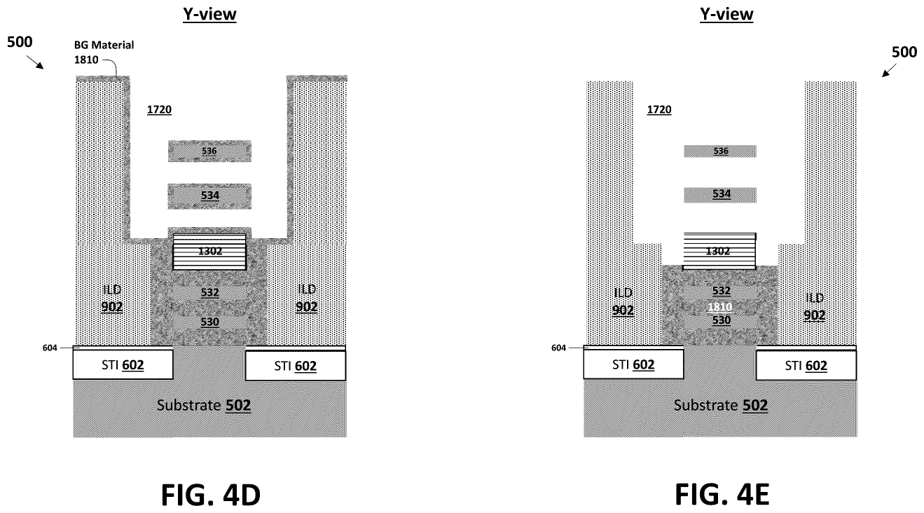

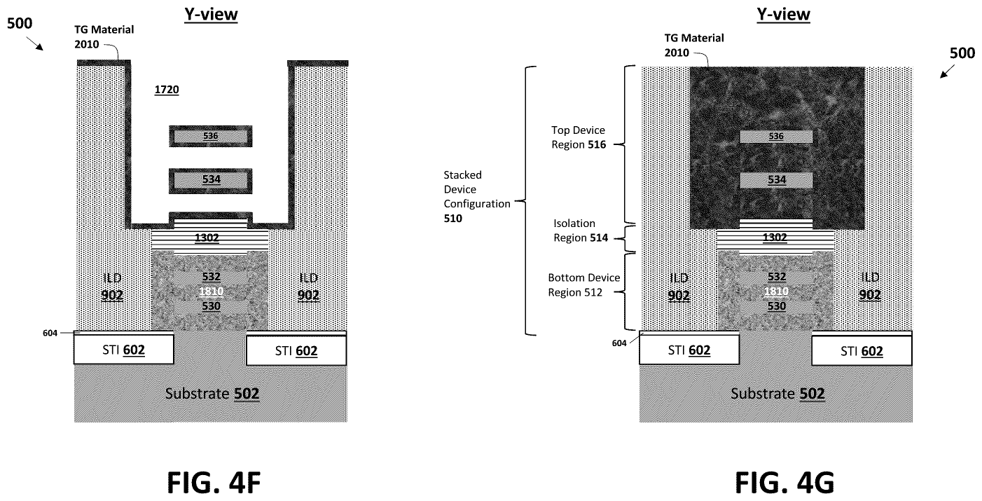

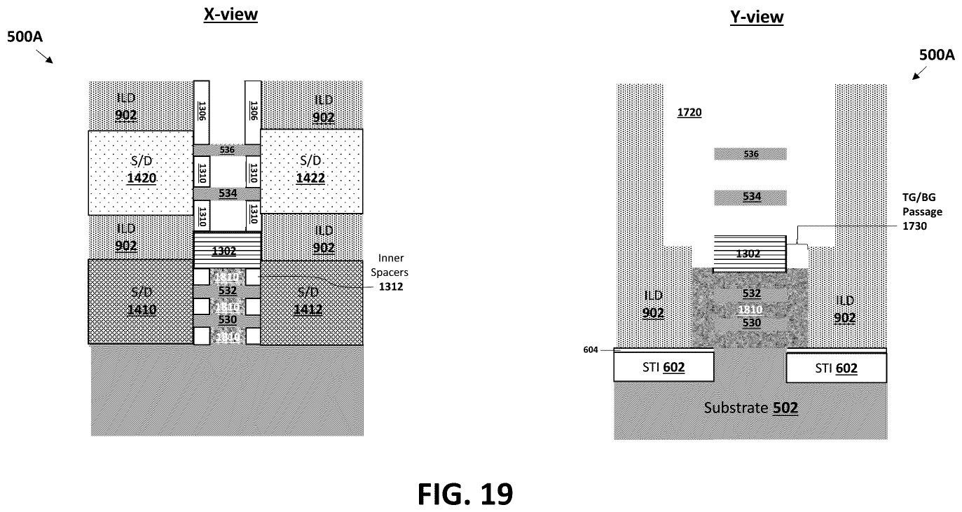

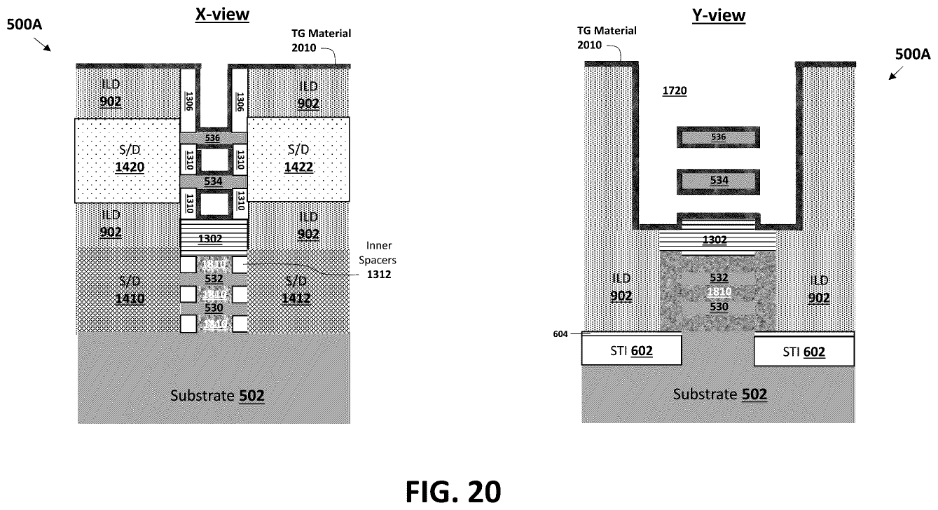

Turning now to a more detailed description of embodiments of the disclosure, FIG. 1 depicts a two-dimensional top-down view of a simplified nanosheet-based reference structure 100 having a nanosheet stack (NS) and a gate (Gate). The nanosheet-based reference structure 100 provides a reference point for the various cross-sectional views (X-view and Y-view) shown in FIGS. 4A-21. More specifically, the X-view is a side view taken along the NS of the nanosheet-based reference structure 100; and the Y-view is an end view taken along the active Gate of the nanosheet-based reference structure 100. Although the cross-sectional diagrams depicted in FIGS. 4A-21 are two-dimensional, the diagrams depicted in FIGS. 4A-21 represent three-dimensional structures. Thus, to assist with visualizing the three-dimensional structures, the top-down view of the nanosheet-based reference structure 100 provides a reference point for the various cross-sectional views (the X-view and the Y-view) shown in FIGS. 4A-21.

Turning now to a more detailed description of aspects of the disclosure, FIG. 2 depicts a three-dimensional view of a portion of an IC wafer 200 having formed thereon a GAA nanosheet FET 201 capable of being used to form a stacked device configuration that incorporates aspects of the disclosure. The basic electrical layout and mode of operation of the GAA nanosheet FET 201 does not differ significantly from a traditional FET. The GAA nanosheet FET 201 is formed on a substrate 202 (e.g., formed from semiconductor material such as silicon), and STI regions 204 electrically isolate the GAA nanosheet FET 201 from other devices on the IC wafer 200. The GAA nanosheet FET 201 includes a nanosheet stack 206 and a gate stack 214, configured and arranged as shown. Each nanosheet stack 206 is formed from spaced-apart nanosheets that extend from one side of the gate stack 214, through the gate stack 214 to an opposite side of the gate stack 214. Each spaced-apart nanosheet is relatively thin (e.g., about 3 nm to about 8 nm thick) and can have a variety of shapes (e.g., sheets, wires and the like). A first end of the nanosheet stack 206 that is not surrounded by the gate stack 214 forms a source region 208 of the GAA nanosheet FET 201. A second end of the nanosheet stack 206 that is not surrounded by the gate stack 214 forms a drain region 210 of the GAA nanosheet FET 201. A central region of the nanosheet stack 206 that is surrounded by the gate stack 214 forms a channel region (not shown separately) of the GAA nanosheet FET 201. The gate stack 214 controls the source to drain current flow. The dimensions of the nanosheet stack 206 establish the effective channel length for the GAA nanosheet FET 201. For ease of illustration, three individual nanosheets and one gate stack 214 are shown in FIG. 2. In practice, GAA nanosheet FETs can be fabricated having any number of nanosheets in the nanosheet stack 206, and any number of gate stacks 214 formed on the substrate 202. Additionally, any number of GAA nanosheet FETs can be included in a stacked device configuration in accordance with aspects of the disclosure. The substrate 202 can be silicon, the STI regions 204 can be an oxide (e.g., silicon oxide), and the nanosheet stack 206 can be silicon.

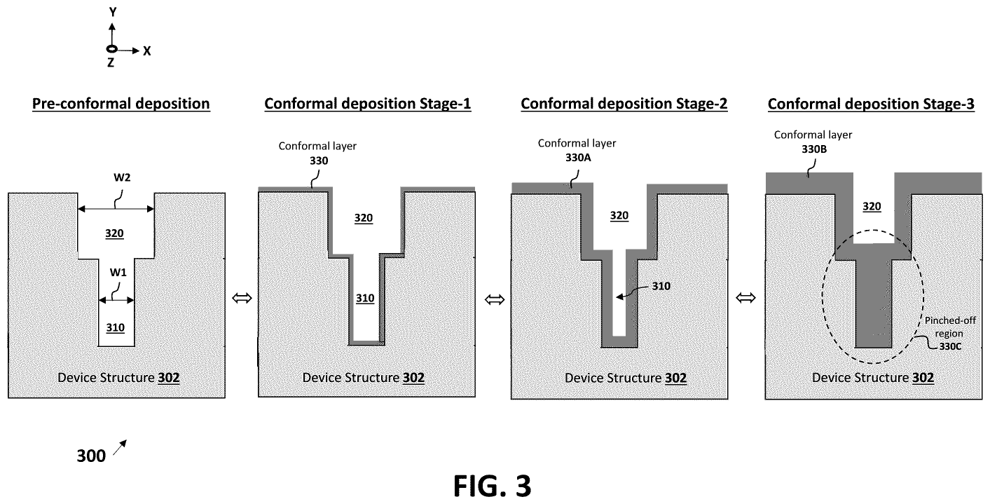

FIG. 3 depicts a sequence of simplified diagrams illustrating a methodology 300 incorporating a novel selective pinch-off operation in accordance with aspects of the disclosure. As depicted by the diagram labeled “Pre-conformal deposition,” a device structure 302 has been formed having a bottom cavity 310 and a top cavity 320. The device structure 302 can take a variety of forms, including but not limited to the various structures that are used to form semiconductor devices (e.g., transistors) on IC wafers. Although the device structure 302 is depicted in two-dimensions (the X direction and the Y direction), the device structure 302 extends in three-dimensions (the X direction, the Y direction, and the Z direction) and provides any suitable shape to the bottom cavity 310 and the top cavity 320. For example, the top-down or X/Z view of the device structure 302 can have a substantially rectangular shape that forms the bottom cavity 310 and the top cavity 320 as two circumferentially enclosed rectangular trenches, one on top of the other. In accordance with aspects of the disclosure, a width dimension (W1) of the bottom cavity 310 is less than a width dimension (W2) of the top cavity 320. In accordance with embodiments of the disclosure, W2 is insufficient to result in a conformal layer 330B (shown as the diagram labeled “Conformal deposition Stage-3”) conformally deposited on exposed surfaces within the top cavity 320 to a first predetermined thickness pinching off in the top cavity 320, and W1 is sufficient to result in the conformal layer 330B conformally deposited in the bottom cavity 310 to the first predetermined thickness pinching off in the bottom cavity 310, thereby forming a pinched-off region 330C that substantially fills the bottom cavity 310.

In accordance with embodiments of the disclosure, the conformal layer 330B is conformally deposited in stages, which are shown in FIG. 3 as Conformal deposition Stage-1, Conformal deposition Stage-2, and Conformal deposition Stage-3. At Conformal deposition Stage-1, conformal layer 330 has been deposited having an initial thickness, and at Conformal deposition Stage-2, the conformal deposition process continues, thus forming conformal layer 330A having an intermediary thickness. At Conformal deposition Stage-3, the conformal deposition process continues, thus forming conformal layer 330B having a final thickness that results in the conformal layer 330B on opposing walls and the bottom surface of the bottom cavity 310 merging or pinching off, thereby forming the pinched-off region 330C in the bottom cavity 310 that substantially fills the bottom cavity 310.

The process used to form the conformal layer 330, 330A, 330B can be any suitable conformal deposition process (e.g., atomic layer depositions (ALD)). In general, when forming a conformal coating of material, the material is deposited everywhere on exposed surfaces of a to-be-coated (TBC) structure (e.g., the device structure 302). The TBC structure is placed in a vacuum chamber. During the ALD process, the gaseous precursors and reactants are alternately pulsed into the vacuum chamber to react with the functional groups (atomic groups in a compound) of the TBC structure or the already deposited layer. New reactive groups are formed on the exposed surfaces of the TBC structure. The reaction is self-limited by the number of functional groups and comes to a halt after a sufficient pulse time. Between pulses, the vacuum chamber is purged so that no gas phase reaction can occur. The reactions are confined to the exposed surfaces of the TBC structure. Accordingly, an ALD cycle typically includes four consecutive steps, namely, a precursor pulse, a purge step, a reactant pulse, and a purge step. The ALD cycle is repeated, depositing films of the same thickness in the sub-nanometer range sequentially. The thickness of the deposited film is defined by the number of ALD cycles. Due to its self-limiting surface reactions, the ALD technique enables conformality of the coating no matter the shape of the surface of the TBC structure.

FIG. 4A depicts a flow diagram illustrating a methodology 400 incorporating a novel selective pinch-off operation in accordance with aspects of the disclosure, and FIGS. 4B-4G depict multiple cross-sectional Y-views of a portion of an IC structure 500 after fabrication operations that further illustrate the methodology 400. It is noted that the sequence in which the blocks 402, 404, 406, 408, 410, 412, 414 of the methodology 400 is for ease of illustration and explanation. In practice, the sequence in which the blocks 402, 404, 406, 408, 410, 412, 414 are performed can be in a different order than shown in FIG. 4. The operations depicted at blocks 402, 404, and 406 correspond to the IC structure 500 after the fabrication operations shown in FIGS. 4B, 4C, and 4D. Referring initially to FIG. 4B, known IC fabrication operations have been used to form the IC structure 500 to the fabrication stage as shown. At the fabrication stage shown in FIG. 4B, the IC structure 500 includes a substrate 502, shallow trench isolation (STI) regions 602, an oxide layer 604, an interlayer dielectric (ILD) region 902, a top gate cavity 1720, a bottom gate cavity 1710, a first nanosheet 534, a second nanosheet 536, a third nanosheet 530, a fourth nanosheet 532, and a first section of an isolation region 1302, configured and arranged as shown. The first nanosheet 534 and the second nanosheet 536 are within the top gate cavity 1720, and the third nanosheet 530 and the fourth nanosheet 532 are within the bottom gate cavity 1710. The first section of the isolation region 1302 is between the top gate cavity 1720 and the bottom gate cavity 1710. The first section of the isolation region 1302 defines TG-to-BG (TG/BG) passages 1730 that connect the top gate cavity 1720 and the bottom gate cavity 1710. The IC structure 500 includes regions that, in the final IC, will define a stacked device configuration in a stacked device configuration region 510, a bottom device in a bottom device region 512, an isolation in an isolation region 514, and a top device in a top device region 516, configured and arranged as shown.

FIG. 4C depicts substantially the same fabrication stage of IC structure 500 shown in FIG. 4B. However, for ease of illustration and explanation, the IC structure 500 shown in FIG. 4C has been annotated to depict various dimensions associated with the top gate cavity 1720, the bottom gate cavity 1710, and the methodology 400 shown in FIG. 4A. As shown in FIG. 4B, TG1 defines a width dimension of the top gate cavity 1720; TG2 defines a space between a sidewall of the first nanosheet 534 and a sidewall of the top gate cavity 1720; and TG2 further defines a space between a sidewall of the second nanosheet 536 and a sidewall of the top gate cavity 1720. TG3 defines a space above the second nanosheet 536; TG4 defines a space between the first nanosheet 534 and the second nanosheet 536; and TG5 defines a space below the first nanosheet 534. Similarly, BG1 defines a width dimension of the bottom gate cavity 1710; BG2 defines a space between sidewalls of the third nanosheet 530 and sidewalls of the bottom gate cavity 1710; BG2 further defines a space between sidewalls of the fourth nanosheet 532 and sidewalls of the bottom gate cavity 1710; BG3 defines a space above the fourth nanosheet 532; BG4 defines a space between the third nanosheet 530 and the fourth nanosheet 532; and BG5 defines a space below the third nanosheet 530. Additionally, BG6 defines a space between sidewalls of the first section of the isolation region 1302 and sidewalls of the bottom gate cavity 1710, which corresponds to the TG/BG passage 1730. In accordance with some embodiments of the disclosure, TG1 is greater than BG1. In some embodiments of the disclosure, TG2 is greater than BG2. In some embodiments of the disclosure, TG3 is greater than BG3. In some embodiments of the disclosure, TG4 is greater than BG4. In some embodiments of the disclosure, TG5 is greater than BG5.

With reference now to FIGS. 4A, 4B, and 4C, at block 402 of the methodology 400, known IC fabrication operations have been used to form the top gate cavity 1720 having the first nanosheet 534, the second nanosheet 536, and dimensions TG1, TG2, TG3, TG4, TG5. At block 404 of the methodology 400, known IC fabrication operations have been used to form the bottom gate cavity 1710 having the third nanosheet 530, the fourth nanosheet 532, and dimensions BG1, BG2, BG3, BG4, BG5, BG6. At block 406 of the methodology 400, known IC fabrication operations have been used to form a first section of the isolation region 1302 between the top gate cavity 1720 and the bottom gate cavity 1710.

At block 408 of the methodology 400, and as shown in FIG. 4D, known IC fabrication operations have been used to conformally deposit a bottom gate material 1810 on exposed surfaces within the top gate cavity 1720 and the bottom gate cavity 1710, where a thickness of the bottom gate material 1810 and/or the dimensions TG1, TG2, TG3, TG4, TG5 are insufficient to result in the bottom gate material 1810 pinching off in the top gate cavity 1720, and where the thickness of the bottom gate material 1810 and/or the dimensions BG1, BG2, BG3, BG4, BG5 are sufficient to result in the bottom gate material 1810 pinching off in the bottom gate cavity 1710.

In accordance with embodiments of the disclosure, the bottom gate material 1810 can be implemented as a high-k metal gate (HKMG), which can be fabricated to include a gate and gate dielectric layers. In general, the gate dielectric layers can include any suitable dielectric material, including but not limited to silicon oxide, silicon nitride, silicon oxynitride, high-k materials, or any combination of these materials. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k dielectric can further include dopants such as lanthanum, aluminum, magnesium.

The gate portion of the HKMG can include any suitable gate conductive material. The conductive material can further include dopants that are incorporated during or after deposition. In some embodiments of the disclosure, the gate portion of the HKMG can further include a work-function setting layer between the gate dielectric layers and the gate. The work-function setting layer can be a work-function metal (WFM) formed from any suitable material. In some embodiments of the disclosure, a conductive material or a combination of multiple conductive materials can serve as both the main conductive element of the gate and the WFM of the gate.

At block 410 of the methodology 400, and as shown in FIG. 4E, known IC fabrication operations have been used to remove the bottom gate material 1810 from the top gate cavity 1720. In embodiments of the disclosure, because the bottom gate material 1810 is around the first nanosheet 534 and the second nanosheet 536, a removal process is required that removes the bottom gate material 1810 from all surfaces of the first nanosheet 534 and the second nanosheet 536. In embodiments of the disclosure, a removal process that removes the bottom gate material 1810 from the first nanosheet 534 and the second nanosheet 536 can be implemented as any suitable selective isotropic etch operation that etches in all directions. As best shown in FIG. 4E, the selective isotropic etch operation used to remove the bottom gate material 1810 from the top gate cavity 1720 will eventually begin to etch portions of the bottom gate material 1810 within the TG/BG passage 1730. At this stage of the selective isotropic etch operation, the first section of the isolation region 1302 covers a first portion of the bottom gate material 1810, and a second portion of the bottom gate material 1810 that is within the TG/BG passage 1730 is exposed to the selective isotropic etchant. In accordance with aspects of the disclosure, the vertical height dimension of the first section of the isolation region 1302, along with the BG6 dimension of the TG/BG passage 1730, can be configured and arranged to slow and/or control the amount of the selective isotropic etchant that reaches and etches the second portion of the bottom gate material 1810 that is within the TG/BG passage 1730. Accordingly, the selective isotropic etchant used to remove the bottom gate material 1810 from the top gate cavity 1720 also reduces a top surface of the second portion of the bottom gate material 1810 that remains in the bottom gate cavity 1710. In some embodiments of the disclosure, the vertical height dimension of the first section of the isolation region 1302 and/or the BG6 dimension of the TG/BG passage 1730 are selected such that the selective isotropic etchant completes the removal of the bottom gate material 1810 from the top gate cavity 1720 before the selective isotropic etchant removes enough of the second portion of the bottom gate material 1810 in the TG/BG passage 1730 that the selective isotropic etchant reaches and begins to isotropically etch (i.e., etch in all directions) the first portion of the bottom gate material 1810 that is beneath the first section of the isolation region 1302.

At block 412 of the methodology 400, and as shown in FIG. 4F, known IC fabrication operations have been used to form a second section of the isolation region 1302 that fills in the TG/BG passage 1730, thereby separating the top gate cavity 1720 from the top gate cavity 1720. At block 414 of the methodology 400, and as shown in FIGS. 4F and 4G, known IC fabrication operations have been used to conformally deposit a top gate material 2010 on exposed surfaces within the top gate cavity 1720, where a thickness of the top gate material 2010 and/or the dimensions TG1, TG2, TG3, TG4, TG5 are sufficient to result in the top gate material 2010 pinching off in the top gate cavity. In some embodiments of the disclosure, the top gate material can be deposited using a non-conformal deposition technique. After the IC fabrication operations at block 414, the IC structure 500 includes a stacked device configuration in the stacked device configuration region 510, a bottom device in the bottom device region 512, an isolation in the isolation region 514, and a top device in the top device region 516, configured and arranged as shown.

In accordance with embodiments of the disclosure, the top gate material 2010 can be implemented as a HKMG, which can be fabricated in substantially the same manner as the HKMG of the bottom gate material 1810. In accordance with aspects of the disclosure, the HKMG of the bottom gate material 1810 and the HKMG of the top gate material 2010 can be different and targeted to correspond to what is needed to form a particular type of the top device (e.g., a p-type FET; an extended gate memory; and the like) in the top device region 516 and form a particular type of the bottom device (e.g., an n-type FET) in the bottom device region 512. For example, the HKMG of the top gate material 2010 can have a different gate size, different gate dielectric layer thickness and different WFM characteristics than the HKMG of the bottom gate material 1810.

In accordance with embodiments of the disclosure, the bottom gate material 1810 is formed around a central region of the third nanosheet 530, thereby forming a channel nanosheet of the third nanosheet 530. In accordance with embodiments of the disclosure, the bottom gate material 1810 is also formed around a central region of the fourth nanosheet 532, thereby forming a channel nanosheet of the fourth nanosheet 532. In accordance with embodiments of the disclosure, the top gate material 2010 is formed around a central region of the first nanosheet 534, thereby forming a channel nanosheet of the first nanosheet 534. In accordance with embodiments of the disclosure, the top gate material 2010 is formed around a central region of the second nanosheet 536, thereby forming a channel nanosheet of the second nanosheet 536.

In accordance with aspects of the disclosure, the methodologies 300, 400 illustrated in FIGS. 3 and 4A-4G provide technical benefits and technical effects. For example, because the space between the first nanosheet 534 and the second nanosheet 536 is greater than a space between the third nanosheet 530 and the fourth nanosheet 532, the novel selective pinch-off operation embodied in the methodologies 300, 400 are used to deposit the bottom gate material 1810 around the third nanosheet 530 and the fourth nanosheet 532, and to further deposit the top gate material 2010, different from the bottom gate material 1810, around the first nanosheet 534 and the second nanosheet 536. In some embodiments of the disclosure, the selective pinch-off operation represented by the methodologies 300, 400 includes conformally depositing the bottom gate material 1810 on exposed surfaces within the top gate cavity 1720 and the top gate cavity 1720. The first nanosheet 534 and the second nanosheet 536 are within the top gate cavity 1720, and the third nanosheet 530 and the fourth nanosheet 532 are within the top gate cavity 1720. The space between the first nanosheet 534 and the second nanosheet 536 is insufficient to result in the conformally deposited bottom gate material 1810 pinching off in the space between the first nanosheet 534 and the second nanosheet 536, and the space between the third nanosheet 530 and the fourth nanosheet 532 is sufficient to result in the conformally deposited bottom gate material 1810 pinching off in the space between the third nanosheet 530 and the fourth nanosheet 532. Subsequent to removing the bottom gate material 1810 from the top gate cavity 1720, a top gate material 2010 is deposited within the top gate cavity 1720, thereby forming the bottom gate material 1810 around the third nanosheet 530 and the fourth nanosheet 532, and further forming the top gate material 2010 around the first nanosheet 534 and the second nanosheet 536.

Without benefit of embodiments of the disclosure, the above-described process of removing the bottom gate material 1810 from the top gate cavity 1720 is challenging because the presence of the first nanosheet 534 and the second nanosheet 536 in the top gate cavity 1720 require the use of an isotropic etch that etches laterally to remove the bottom gate material 1810 from the space between the first nanosheet 534 and the second nanosheet 536. However, embodiments of the disclosure recognize and leverage a heretofore unappreciated observation that, if the space between the first nanosheet 534 and the second nanosheet 536 in the top gate cavity 1720 is not sufficiently greater than the space between the third nanosheet 530 and the fourth nanosheet 532 in the bottom gate cavity 1710, an isotropic etch that is applied long enough to remove the bottom gate material 1820 from the top gate cavity 1720 will also remove an unacceptable amount of the bottom gate material 1810 from the bottom gate cavity 1710, thereby requiring complicated, time consuming, and unreliable operations to rebuild the removed portions of the bottom gate material 1810 before the top gate material 2010 is deposited. Because embodiments of the disclosure provide a space between the first nanosheet 534 and the second nanosheet 536 that is insufficient to result in the conformally deposited bottom gate material 1810 pinching off in the space between the first nanosheet 534 and the second nanosheet 536, and because embodiments of the disclosure substantially concurrently provide a space between the third nanosheet 530 and the fourth nanosheet 532 that is sufficient to result in the conformally deposited bottom gate material 1810 pinching off in the space between the third nanosheet 530 and the fourth nanosheet 532, an isotropic etch that is applied long enough to remove the bottom gate material 1810 from the top gate cavity 1720 will not also remove an unacceptable amount of the bottom gate material 1810 from the bottom gate cavity 1710, thereby eliminating the need to apply complicated, time consuming, and unreliable operations to rebuild removed portions of the bottom gate material 1810 before the top gate material 2010 is deposited.

The above-described embodiments of the disclosure provide additional technical benefits and technical effects by providing a width dimension TG1 of the top gate cavity 1720 that is different from a width dimension BG1 of the bottom gate cavity 1710. Providing a relative width difference between the top gate cavity 1720 and the bottom gate cavity 1710 enables the top gate formed from the top gate material 2010 to be larger than the bottom gate formed from the bottom gate material 1810, thereby enabling the top gate to be fabricated such that it includes a relatively thick gate dielectric. The relatively thick gate dielectric can be implemented as a so-called extended-gate (EG) dielectric, which is configured to tolerate larger gate threshold voltages (e.g., larger than required for transistor switching operations) that are required by electronic devices such as MOSFETs that function as memory cells. In some embodiments of the disclosure, the EG dielectric thickness is selected to increase the threshold voltage V_{T} that can be tolerated by top gate. In some embodiments of the disclosure, EG dielectric can include high-k dielectric layers operable to modify a work function property of the top gate.

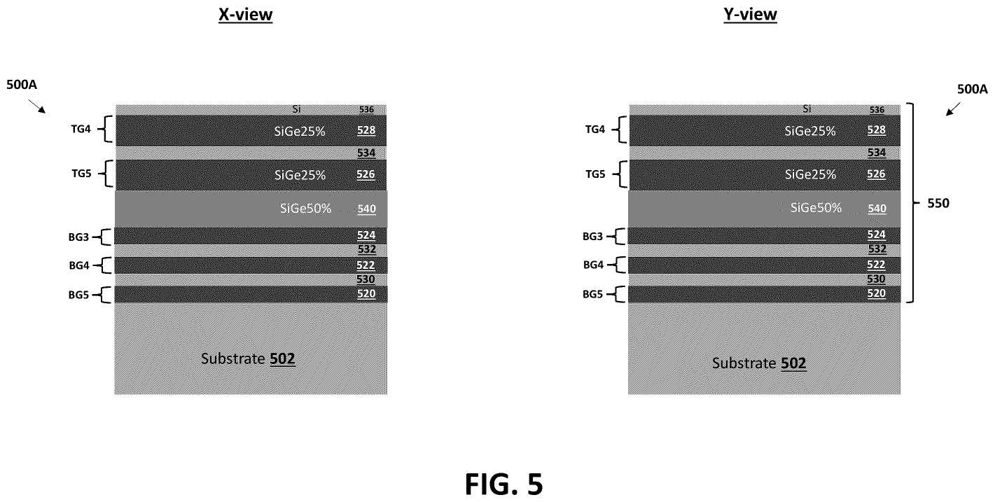

FIGS. 5-21 depict multiple cross-sectional views (i.e., an X-view and a Y-view) of a portion of an IC structure 500A after IC fabrication operations that include a novel selective pinch-off operation in accordance with aspects of the disclosure. Turning initially to FIG. 5, there are depicted cross-sectional views (i.e., an X-view and a Y-view) of the IC structure 500A after initial fabrication operations in accordance with aspects of the present disclosure. As shown in FIG. 5, an initial wafer is formed that includes a substrate 502 and a nanosheet stack 550 over the substrate 502. The nanosheet stack 550 includes alternating layers of non-sacrificial nanosheets and sacrificial nanosheets. The non-sacrificial nanosheets are implemented as the first nanosheet 534, the second nanosheet 536, the third nanosheet 530, and the fourth nanosheet 532. The sacrificial nanosheets are implemented as sacrificial nanosheet 520, sacrificial nanosheet 522, sacrificial nanosheet 524, sacrificial nanosheet 526, sacrificial nanosheet 528, and sacrificial nanosheet 540. After downstream fabrication operations are performed to remove the sacrificial nanosheets 520, 522, 524, 526, 528, 540, the nanosheet stack 550 will include the non-sacrificial nanosheets implemented as the first nanosheet 534, the second nanosheet 536, the third nanosheet 530, and the fourth nanosheet 532.

In embodiments of the disclosure, the substrate 502 can be a bulk configuration. The substrate 502 can be formed from silicon or it can be formed from materials other than silicon, e.g., silicon-germanium, a III-V compound semiconductor material, and the like. The terms “substrate” or “semiconductor substrate” should be understood to cover all semiconducting materials and all forms of such materials.

In accordance with aspects of the disclosure, the alternating layers of non-sacrificial nanosheets (implemented as the first nanosheet 534, the second nanosheet 536, the third nanosheet 530, and the fourth nanosheet 532) and sacrificial nanosheets 520, 522, 524, 526, 528, 540 are formed by epitaxially growing one nanosheet layer then the next until the desired number and desired thicknesses of the nanosheet layers are achieved. Epitaxial materials can be grown from gaseous or liquid precursors using, for example, vapor-phase epitaxy (VPE), molecular-beam epitaxy (MBE), liquid-phase epitaxy (LPE), or other suitable process. Epitaxial silicon, silicon germanium, and/or carbon doped silicon (Si:C) silicon can be doped during deposition (in-situ doped) by adding dopants, n-type dopants (e.g., phosphorus or arsenic) or p-type dopants (e.g., boron or gallium), depending on the type of transistor.

In embodiments of the disclosure, each of the non-sacrificial nanosheets (implemented as the first nanosheet 534, the second nanosheet 536, the third nanosheet 530, and the fourth nanosheet 532) and the sacrificial nanosheets 520, 522, 524, 526, 528, 540 can have a vertical direction thickness in the range from about 5 nm to about 20 nm, in the range from about 10 nm to about 15 nm, or about 10 nm. Other vertical direction thicknesses are contemplated. In accordance with aspects of the disclosure, the vertical thickness dimension of sacrificial nanosheets 526, 528 correspond to TG5 and TG4, respectively (shown in FIG. 4C); the vertical thickness dimension of sacrificial nanosheet 540 corresponds to a vertical thickness dimension of the first section of the isolation region 1302 (shown in FIG. 4C), and the vertical thickness dimension of sacrificial nanosheets 520, 522, 524 correspond to BG5, BG4, and BG3, respectively (shown in FIG. 4C). Although ten (10) alternating layers of non-sacrificial nanosheets (implemented as the first nanosheet 534, the second nanosheet 536, the third nanosheet 530, and the fourth nanosheet 532) and sacrificial nanosheets 520, 522, 524, 526, 528, 540 are depicted in the figures, any number and/or type of alternating layers of non-sacrificial nanosheets and sacrificial nanosheets can be provided.

In some embodiments of the disclosure, the non-sacrificial nanosheets (implemented as the first nanosheet 534, the second nanosheet 536, the third nanosheet 530, and the fourth nanosheet 532) can be Si. In some embodiments of the disclosure, the sacrificial nanosheet 540 can be about SiGe 50%. In some embodiments of the disclosure, the sacrificial nanosheets 526, 528 can be about SiGe 25%. The notation “SiGe 25%” is used to indicate that about 20% of the SiGe material is Ge and about 80% of the SiGe material is Si.

In embodiments of the disclosure, the sacrificial nanosheets 540, 526, 528 are relatively thick and formed from SiGe with each having a Ge percentage that is sufficiently greater than the Ge percentage in other portions of the IC structure 500A to provide etch selectivity between the sacrificial nanosheets 540, 526, 528 and the remaining portions of the IC structure 500A.

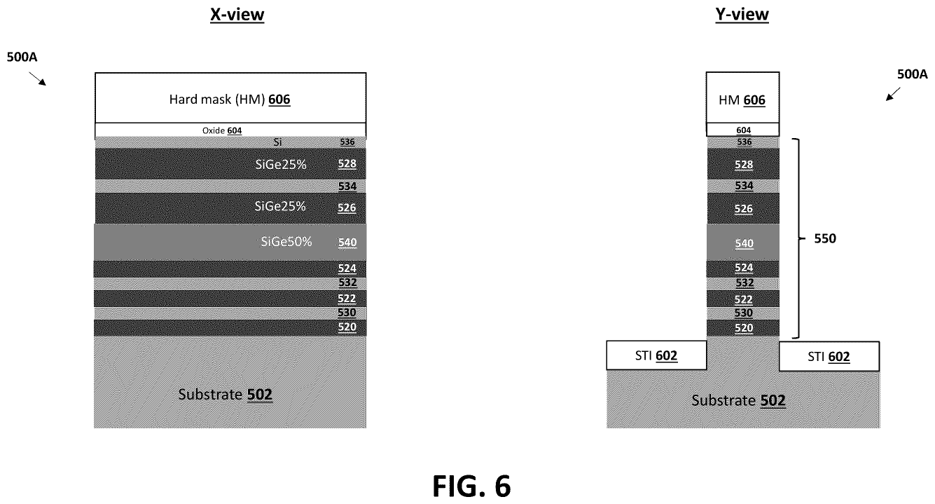

FIG. 6 depicts cross-sectional views of the IC structure 500A after known IC fabrication operations have been used to form an oxide layer (e.g., SiO₂) 604 and a hard mask (HM) 606 on the IC structure 500A. The HM 606 can be formed by depositing a HM layer (not shown) over the IC structure 500A. The HM layer and the resulting HM 606 can be any suitable material, including amorphous silicon (aSi). The HM layer is patterned and etched. The IC structure 500A is etched to define an elongated fin-shape version of the nanosheet stack 550 and a portion of the substrate 502. Known IC fabrication operations have also been used to remove to deposit a dielectric material (not shown) over the IC structure 500A. The dielectric material is planarized or recesses to form shallow trench isolation (STI) regions 602, which prevent electrical current from leaking between adjacent semiconductor device components of the substrate 502. The STI regions 602 can include any suitable dielectric material, such as, for example, an oxide (e.g., SiO₂).

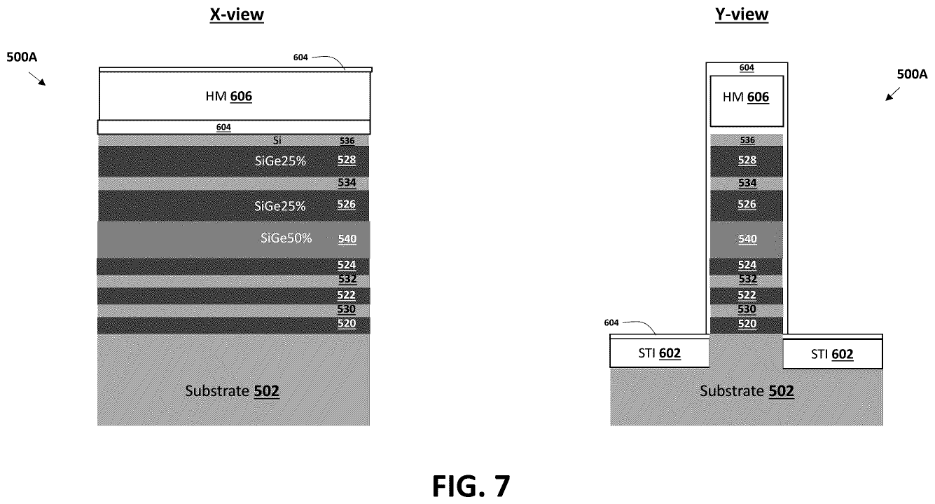

FIG. 7 depicts cross-sectional views of the IC structure 500A after known IC fabrication operations have been used to deposit an additional layer of the dielectric material over the IC structure 500A.

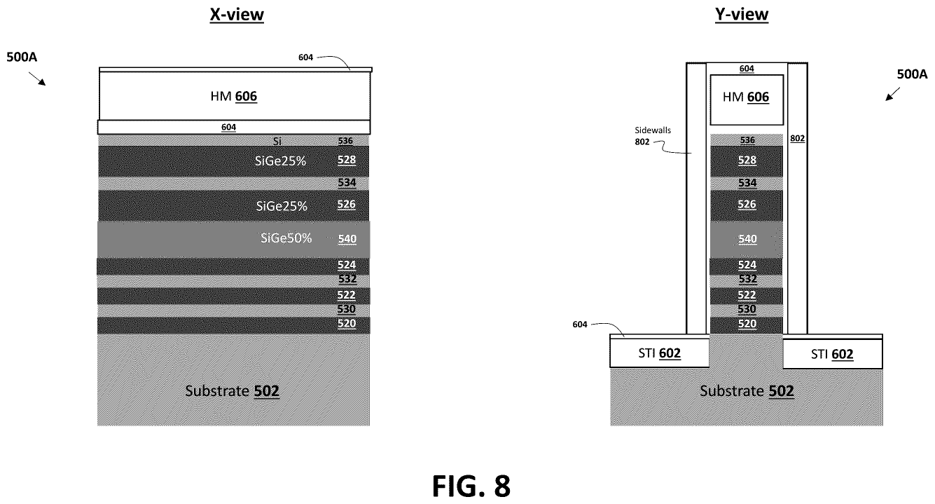

FIG. 8 depicts cross-sectional views of the IC structure 500A after known IC fabrication operations (e.g., conformal deposition followed by a direction etch back) have been used to form sidewalls 802, as best shown in the Y-view. A suitable material for the sidewalls 802 is aSi.

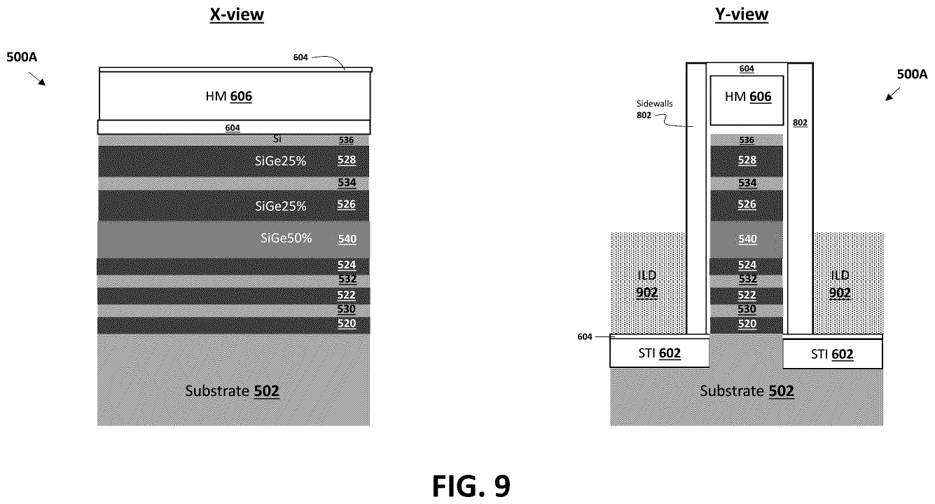

FIG. 9 depicts cross-sectional views of the IC structure 500A after known IC fabrication operations have been used to deposit ILD regions 902. In accordance with embodiments of the disclosure, the ILD regions 902 shown in FIG. 9 define sidewall portions of the bottom gate cavity 1710 (shown in FIG. 4B). In aspects of the disclosure, the ILD regions 902 can be formed from a low-k dielectric (e.g., k less than about 4) and/or an ultra-low-k (ULK) dielectric (e.g., k less than about 2.5).

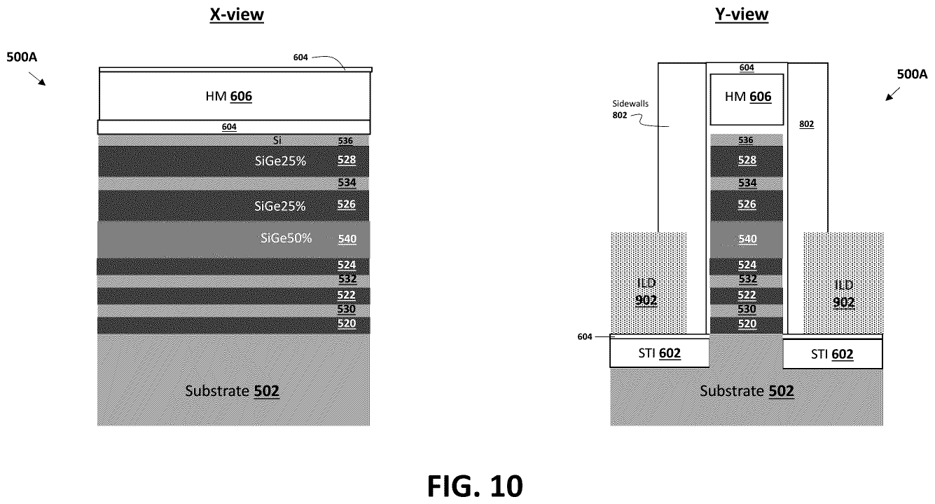

FIG. 10 depicts cross-sectional views of the IC structure 500A after known IC fabrication operations (e.g., conformal deposition followed by a direction etch back) have been used to form an additional region of the sidewalls 802, as best shown in the Y-view. The additional region of the sidewalls 802 extend over a portion of a top surface of the ILD regions 902. A suitable material for the additional regions of the sidewalls 802 is aSi.

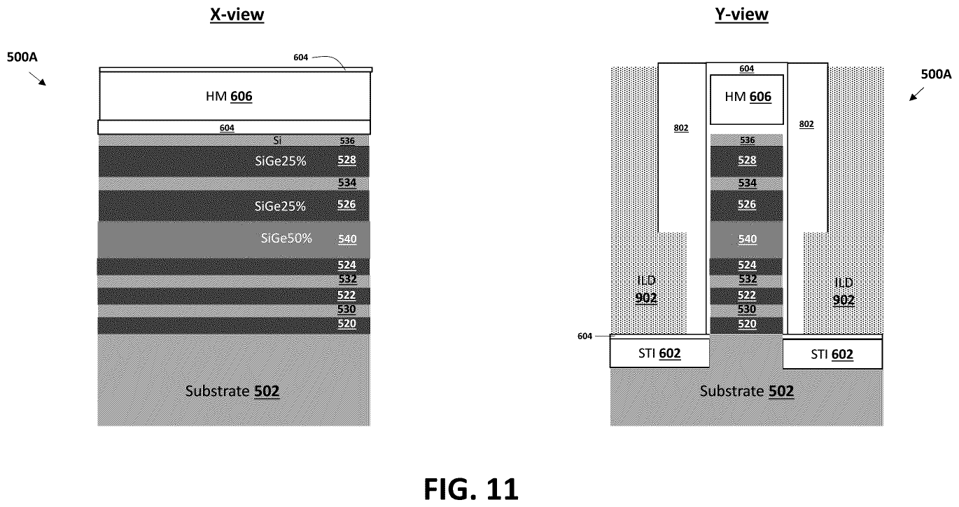

FIG. 11 depicts cross-sectional views of the IC structure 500A after known IC fabrication operations have been used to deposit an additional region of the ILD regions 902, which is followed by a planarization operation (e.g., chemical mechanical planarization (CMP)). In accordance with embodiments of the disclosure, the additional region of the ILD regions 902 defines sidewall portions of the top gate cavity 1720 (shown in FIG. 4B). In aspects of the disclosure, the additional region of the ILD regions 902 can be formed from a low-k dielectric (e.g., k less than about 4) and/or an ultra-low-k (ULK) dielectric (e.g., k less than about 2.5).

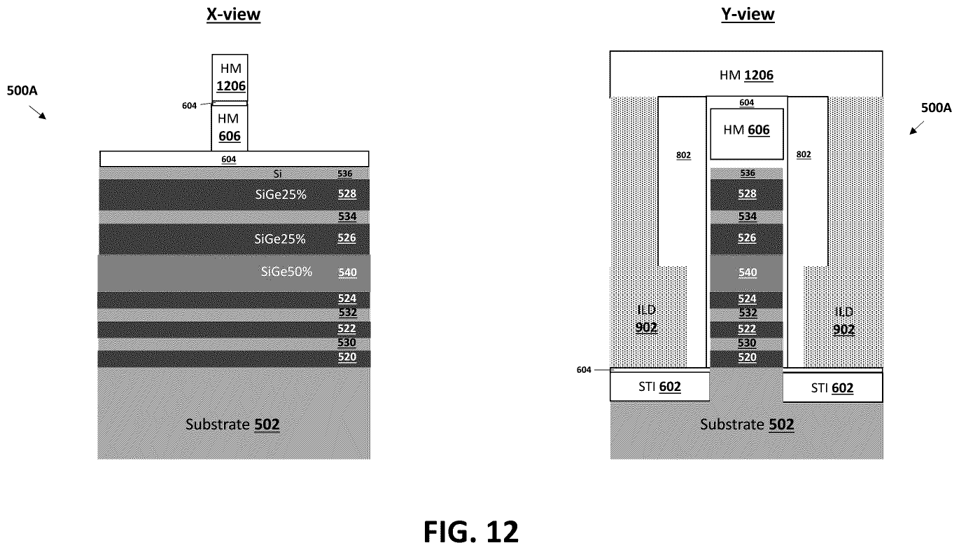

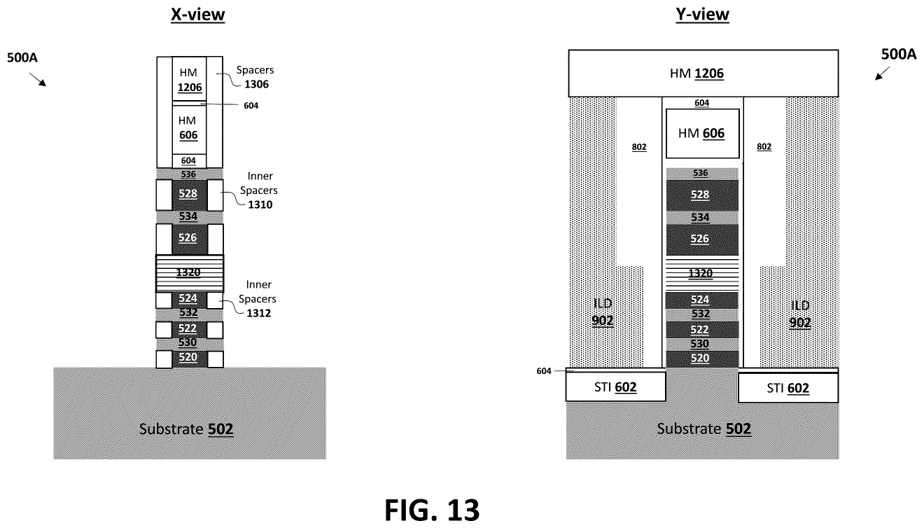

FIG. 12 depicts cross-sectional views of the IC structure 500A after known IC fabrication operations have been used to form a HM 1206 on the IC structure 500A to perform various gate-related fabrication operations shown in FIG. 13. The HM 1206 can be formed by depositing a HM layer (not shown) over the IC structure 500A. The HM layer and the resulting HM 1206 can be any suitable material, including amorphous silicon (aSi).

FIG. 13 depicts cross-sectional views of the IC structure 500A after known IC fabrication operations have been applied according to embodiments of the disclosure. More specifically, additional portions of the oxide layer 604 and the nanosheet stack 550 have been etched based on the HM 1206, and multiple known IC fabrication operations have been used to form gate spacers 1306, and inner spacers 1310, configured and arranged as shown. A variety of techniques are available to form these structures, and such techniques are well-known to those skilled in the relevant arts. Accordingly, specific illustrations and detailed descriptions of examples of such fabrication techniques have not been provided in the interest of brevity, and instead, the following summary descriptions of the structures formed in FIG. 13 is provided.

Referring still to FIG. 13, known IC fabrication operations have been used to deposit and etch dielectric material to form gate spacers 1306 on sidewalls of the HMs 1206, 606. In embodiments of the disclosure, the gate spacers 1306 can be formed from any suitable dielectric material including, for example, silicon oxide, silicon nitride, silicon oxynitride, SiBCN, SiOCN, SiOC, or any suitable combination of those materials. In some embodiments of the disclosure, the gate spacers 1306 can be a low-k dielectric material.

Referring still to FIG. 13, known IC fabrication operations have been used to partially remove end regions of the SiGe sacrificial nanosheets 526 and 528 to form end region or inner spacer cavities in which the inner spacers 1310 are formed. The inner spacers 1310 can be silicon nitride, silicoboron carbonitride, silicon carbonitride, silicon carbon oxynitride, or any other type of dielectric material (e.g., a dielectric material having a dielectric constant k of less than about 5). Similarly, known IC fabrication operations have been used to partially remove end regions of the SiGe sacrificial nanosheets 520, 522, and 524 to form end region or inner spacer cavities in which the inner spacers 1312 are formed. The inner spacers 1312 can be silicon nitride, silicoboron carbonitride, silicon carbonitride, silicon carbon oxynitride, or any other type of dielectric material (e.g., a dielectric material having a dielectric constant k of less than about 5).

Referring still to FIG. 13, known IC fabrication operations have been used to selectively remove the SiGe 50% sacrificial nanosheet 540 and replace it with the first section of the isolation region 1302. An isotropic etch can be performed that is selective to remove the relatively thicker and higher Ge percentage SiGe sacrificial nanosheet 540 while not removing the remaining portions of the IC structure 500A. An example etchant that selectively etches the relatively thicker and higher Ge percentage SiGe sacrificial nanosheet 540 can include a vapor phase hydrogen chloride (HCl) at a suitable temperature and pressure. In embodiments of the disclosure, the first section of the isolation region 1302 provides part of the isolation element that provides dielectric isolation between the top device region 516 (shown in FIG. 4B) and the bottom device region 512 (shown in FIG. 4B) of the stacked device configuration region 510 (shown in FIG. 4B). In embodiments of the disclosure, the first section of the isolation region 1302 can be any suitable dielectric material, including, for example, silicon oxide, silicon nitride, silicon oxynitride, SiBCN, SiOCN, SiOC, or any suitable combination of those materials. The dielectric material used to form the first section of the isolation region 1302 can be deposited using ALD, CVD, or any other suitable deposition technique. Any excess deposited dielectric material can be removed by a suitable selective isotropic etching process.

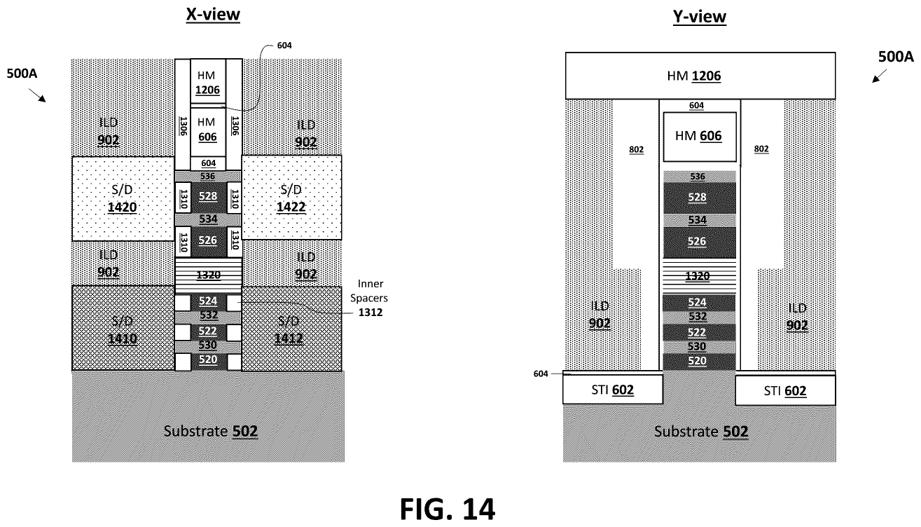

FIG. 14 depicts cross-sectional views of the IC structure 500A after known IC fabrication operations have been applied according to embodiments of the disclosure. More specifically, known IC fabrication operations have been used to form doped S/D regions 1410, 1412. In embodiments of the disclosure, an epitaxial growth process can be used to grow the doped S/D regions 1410, 1412 from exposed ends of the third nanosheet 530 and the fourth nanosheets 532. In embodiments of the disclosure, the doped S/D regions 1410, 1412 can be epitaxially grown from gaseous or liquid precursors using, for example, vapor-phase epitaxy (VPE), molecular-beam epitaxy (MBE), liquid-phase epitaxy (LPE), or other suitable process. In embodiments of the disclosure where the doped S/D regions are n-type, the doped S/D regions 1410, 1412 can be doped during deposition (e.g., in-situ doped) by adding dopants such as n-type dopants (e.g., phosphorus or arsenic) during the above-described methods of forming the n-type doped S/D regions 1010. In embodiments of the disclosure where the doped S/D regions are p-type, the doped S/D regions 1410, 1412 can be doped during deposition (e.g., in-situ doped) by adding dopants such as p-type dopants (e.g., Ga, B, BF₂, or Al) during the above-described methods of forming the doped S/D regions 1410, 1412. Subsequent to forming the doped S/D regions 1410, 1412, known IC fabrication operations are used to deposit additional ILD regions 902 to fill in open spaces and stabilize the IC structure 500A. Subsequent to forming the additional ILD regions 902 shown in FIG. 14, substantially the same operations used to form the doped S/D regions 1410, 1412 are used to form doped S/D regions 1420, 1422 extending from exposed ends of the first nanosheet 534 and the second nanosheet 536. The doped S/D regions 1410, 1412 and the doped S/D regions 1420, 1422 can be provided in any combination of n-type and p-type doping. Subsequent to forming the doped S/D regions 1420, 1422, known IC fabrication operations are used to deposit then planarize additional ILD regions 902 to fill in open spaces, stabilize the IC structure 500A and prepare the IC structure 500A for additional downstream processing.

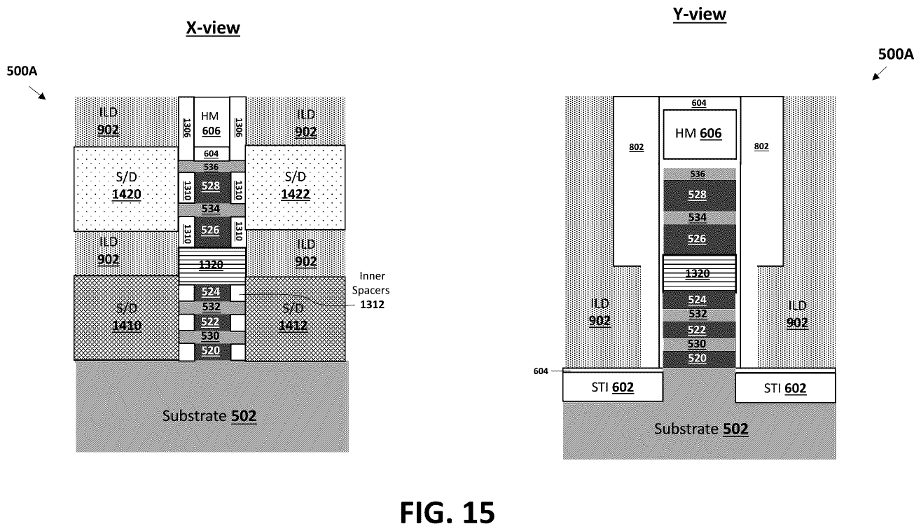

FIG. 15 depicts cross-sectional views of the IC structure 500A after known IC fabrication operations have been used to remove the HM 1206 and planarize the IC structure 500A.

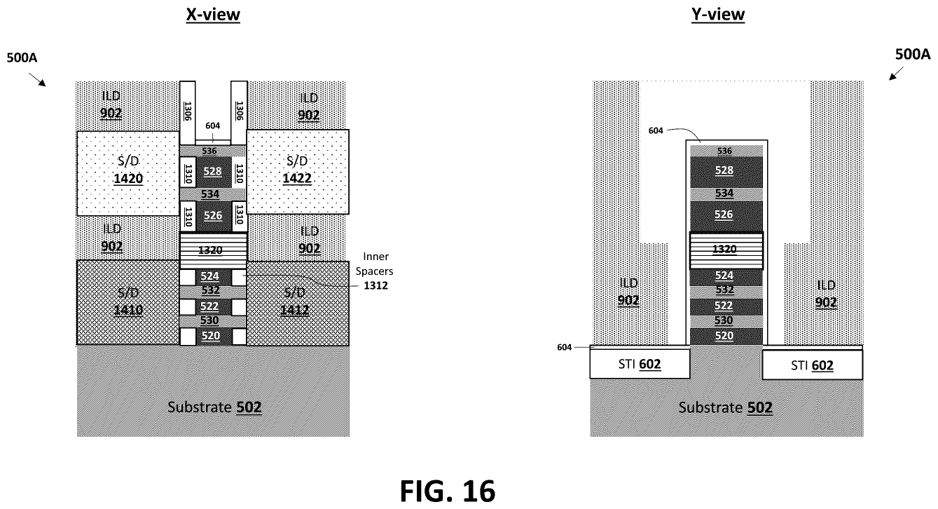

FIG. 16 depicts cross-sectional views of the IC structure 500A after known IC fabrication operations have been used to remove the HM 606 and the sidewalls 802. planarize the IC structure 500A.

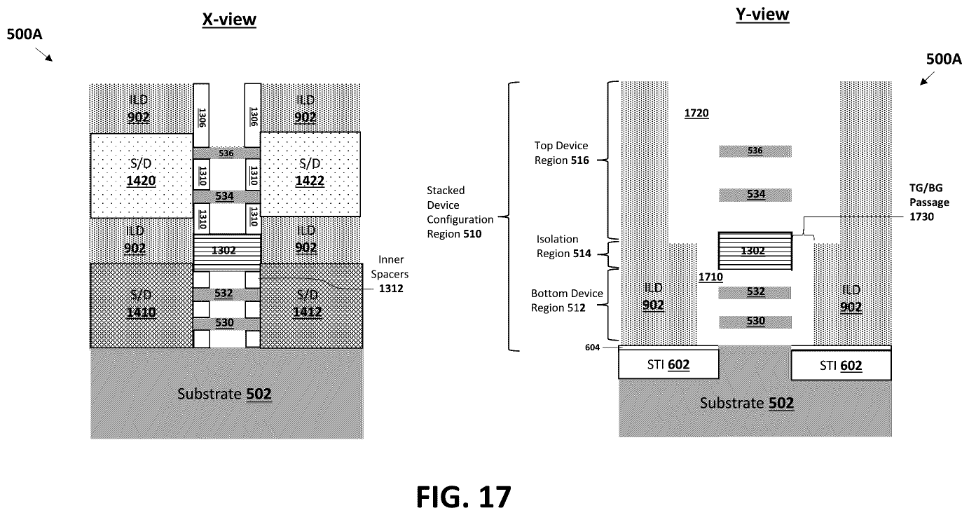

FIG. 17 depicts cross-sectional views of the IC structure 500A after known IC fabrication operations have been used to remove the remaining dielectric/oxide layer 604 and the remaining SiGe sacrificial nanosheets 520, 522, 524, 526, 528 (shown in FIG. 16) selective to the Si non-sacrificial nanosheets (implemented as the first nanosheet 534, the second nanosheet 536, the third nanosheet 530, and the fourth nanosheet 532). In embodiments of the disclosure, because the SiGe sacrificial nanosheets 520, 522, 524, 526, 528 are formed from SiGe, they can be selectively etched with respect to the Si nanosheets 530, 532, 534, 536 using, for example, a vapor phase HCL gas isotropic etch process. After the fabrication operations depicted in FIG. 17, the IC structure 500A has substantially the same structure as the IC structure 500 shown in FIGS. 4B, 4C and previously described herein.

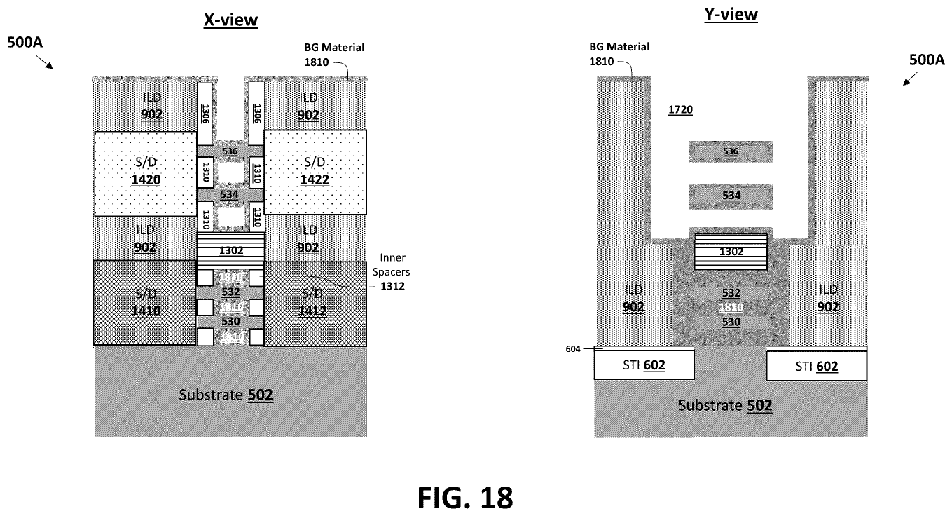

The operations depicted in FIGS. 18, 19, 20, 21 for the IC structure 500A are substantially the same as the operations described in the methodology 400 (shown in FIG. 4A), illustrated by the IC structures 500 shown in FIGS. 4D, 4E, 4F, 4G, and previously described herein.

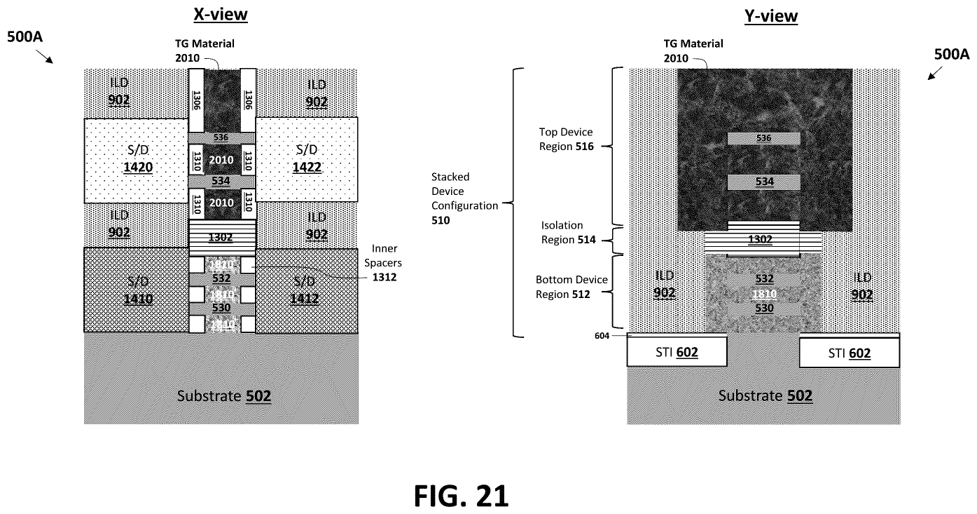

Additional IC fabrication operations can be applied to the IC structure 500A shown in FIG. 21 to make the appropriate electrical contacts to the top gate material 2010, the bottom gate material 1810, the doped S/D regions 1410, 1412, and the doped S/D regions 1420, 1422.

Accordingly, it can be seen from the foregoing detailed description that embodiments of the disclosure address the problems associated with using an isotropic etch to remove the bottom gate material from the top region of the gate cavity by providing spacing around the nanosheets in the top region of the gate cavity that is insufficient to result in a conformally deposited bottom gate material pinching off in the top region of the gate cavity, and by further providing spacing around the nanosheets in the bottom region of the gate cavity that is sufficient to result in the conformally deposited bottom gate material pinching off in the bottom region of the gate cavity. Because embodiments of the disclosure provide spacing around the nanosheets in the top region of the gate cavity that is insufficient to result in a conformally deposited bottom gate material pinching off in the top region of the gate cavity while also providing spacing around the nanosheets in the bottom region of the gate cavity that is sufficient to result in the conformally deposited bottom gate material pinching off in the top region of the gate cavity, an isotropic etch that is applied long enough to remove the bottom gate material from the top region of the gate cavity will not also remove an unacceptable amount of the bottom gate material from the bottom region of the gate cavity, thereby eliminating the need to apply complicated, time consuming, and unreliable operations to rebuild removed portions of the bottom gate material before the top gate material is deposited.

Additionally, by providing a width dimension of the top gate that is different from a width dimension of the bottom gate, embodiments of the disclosure facilitate the efficient fabrication of a top gate having a larger width dimension than the bottom gate, thereby enabling the top gate to be fabricated such that it includes a relatively thick gate dielectric. The relatively thick gate dielectric can be implemented as a so-called extended-gate (EG) dielectric, which is configured to tolerate larger gate threshold voltages (e.g., larger than required for transistor switching operations) that are required by electronic devices such as MOSFETs that function as memory cells. In some embodiments of the disclosure, the EG dielectric thickness is selected to increase the threshold voltage V_{T} that can be tolerated by top gate. In some embodiments of the disclosure, EG dielectric can include high-k dielectric layers operable to modify a work function property of the top gate.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

The term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “under,” “lower,” “above,” “over,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

The phrase “selective to,” such as, for example, “a first element selective to a second element,” means that the first element can be etched and the second element can act as an etch stop.

The term “conformal” (e.g., a conformal layer) means that the thickness of the layer is substantially the same on all surfaces, or that the thickness variation is less than 15% of the nominal thickness of the layer.

References in the specification to terms such as “vertical,” “horizontal,” “lateral,” etc. are made by way of example, and not by way of limitation, to establish a frame of reference. Terms such as “horizontal” and “lateral” refer to a direction in a plane parallel to a top surface of a semiconductor substrate, regardless of its actual three-dimensional spatial orientation. Terms such as “vertical” and “normal” refer to a direction perpendicular to the “horizontal” and “lateral” direction.

As previously noted herein, for the sake of brevity, conventional techniques related to semiconductor device and IC fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor structure according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. An integrated circuit (IC) comprising:
a top device; and
a bottom device positioned under the top device;
wherein the top device comprises a first nanosheet and a second nanosheet;
wherein the bottom device comprises a third nanosheet and a fourth nanosheet; and
wherein a space between the first nanosheet and the second nanosheet is greater than a space between the third nanosheet and the fourth nanosheet.

2. The IC of claim 1 further comprising:
a stacked device configuration comprising:
the top device;
the bottom device; and
an isolation region operable to electrically isolate the bottom device from the top device;
a top gate around exposed surfaces of the first nanosheet and the second nanosheet; and
a bottom gate around exposed surface of the third nanosheet and the fourth nanosheet.

3. The IC of claim 2, wherein a width dimension of the top gate is different from a width dimension of the bottom gate.

4. The IC of claim 2, wherein a work function of the top gate is different from a work function of the bottom gate.

5. The IC of claim 4 further comprising:
top source or drain (S/D) regions electronically coupled to the first nanosheet; and
bottom S/D regions electronically coupled to the third nanosheet;
wherein a doping type of the top S/D regions is different from a doping type of the bottom S/D regions.

6. An integrated circuit (IC) comprising:
a top channel associated with a first device and comprising a first nanosheet stack;
wherein the first nanosheet stack comprises a first nanosheet and a second nanosheet; and
a bottom channel positioned below the top channel, associated with a second device, and comprising a second nanosheet stack;
wherein the second nanosheet stack comprises a third nanosheet and a fourth nanosheet; and
wherein a space between the first nanosheet and the second nanosheet is greater than a space between the third nanosheet and the fourth nanosheet.

7. The IC of claim 6 further comprising a top gate around exposed surfaces of the first nanosheet and the second nanosheet.

8. The IC of claim 7 further comprising a bottom gate around exposed surface of the third nanosheet and the fourth nanosheet.

9. The IC of claim 8, wherein a width dimension of the top gate is different from a width dimension of the bottom gate.

10. The IC of claim 8, wherein a work function of the top gate is different from a work function of the bottom gate.

11. The IC of claim 8, wherein:
a width dimension of the top gate is different from a width dimension of the bottom gate; and
a work function of the top gate is different from a work function of the bottom gate.

12. The IC of claim 11 further comprising:
top source or drain (S/D) regions electronically coupled to the top channel; and
bottom S/D regions electronically coupled to the bottom channel.

13. The IC of claim 12, wherein a doping type of the top S/D regions is different from a doping type of the bottom S/D regions.

14. The IC of claim 13, wherein:
the first device comprises an n-type transistor; and
the second device comprises a p-type transistor.

15. The IC of claim 13, wherein:
the first device comprises a p-type transistor; and
the second device comprises an n-type transistor.

16. A method of performing integrated circuit (IC) fabrication operations, the method comprising:
performing a selective pinch-off operation comprising:
forming a top gate cavity having a first nanosheet and a second nanosheet within the top gate cavity;
forming a bottom gate cavity having a third nanosheet and a fourth nanosheet within the bottom gate cavity; and
depositing a bottom gate material within the top gate cavity and the bottom gate cavity;
wherein a space between the first nanosheet and the second nanosheet is insufficient to result in the bottom gate material, when deposited, pinching off in the space between the first nanosheet and the second nanosheet; and
wherein a space between the third nanosheet and the fourth nanosheet is sufficient to result in the bottom gate material, when deposited, pinching off in the space between the third nanosheet and the fourth nanosheet.

17. The method of claim 16 further comprising, subsequent to removing the bottom gate material from top gate cavity, depositing a top gate material within the top gate cavity.

18. The method of claim 17 further comprising forming a first section of an isolation region operable to define a passage that connects the top gate cavity and the bottom gate cavity.

19. The method of claim 18, wherein the first section of the isolation region is operable to:
block an etchant in the top gate cavity from accessing a first portion of the bottom gate material in the bottom gate cavity; and
allow the etchant in the top gate cavity to access a second portion of the bottom gate material in the bottom gate cavity.

20. The method of claim 19, wherein the first portions of the bottom gate material is larger than the second portion of the bottom gate material.
